(19) United States
(12) Patent Application Publication
(10) Pub. No.: US 2022/0334492 A1
(43) Pub. Date: Oct. 20, 2022

(54) METHOD FOR MANUFACTURING CONDUCTIVE SUBSTRATE, CONDUCTIVE SUBSTRATE, TOUCH SENSOR, ANTENNA, AND ELECTROMAGNETIC WAVE SHIELDING MATERIAL

(71) Applicant: FUJIFILM Corporation, Tokyo (JP)

(72) Inventor: Shinichi KANNA, Fujinomiya-shi (JP)

(73) Assignee: FUJIFILM Corporation, Tokyo (JP)

(21) Appl. No.: 17/848,924

(22) Filed: Jun. 24, 2022

Related U.S. Application Data
(63) Continuation of application No. PCT/JP2020/048262, filed on Dec. 23, 2020.

(30) Foreign Application Priority Data
Dec. 25, 2019 (JP) 2019-234519

(51) Int. Cl. G03F 7/42; G03F 7/039; H05K 9/00

(52) U.S. Cl. CPC G03F 7/425; G03F 7/039; H05K 9/0073; H01L 21/027

(57) ABSTRACT

A first object of the present invention is to provide a method of manufacturing a conductive substrate having a low defect ratio. In addition, a second object of the present invention is to provide a conductive substrate that is obtained using the method of manufacturing a conductive substrate. In addition, a third object of the present invention is to provide a touch sensor, an antenna, and an electromagnetic wave shielding material that include the conductive substrate.

The method of manufacturing a conductive substrate is a method of manufacturing a conductive substrate including a substrate and a patterned conductive layer that is disposed on the substrate, the method including: a step X1, a step X2, a step X3, a step X4, a step X6, a step X7, and a step X8 in this order, in which in the step X4, a photosensitive resin layer is substantially insoluble in a conductive composition.

### CROSS-REFERENCE TO RELATED APPLICATIONS

This application is a Continuation of PCT International Application No. PCT/JP2020/048262 filed on Dec. 23, 2020, which claims priority under 35 U.S.C. § 119(a) to Japanese Patent Application No. 2019-234519 filed on Dec. 25, 2019. Each of the above applications is hereby expressly incorporated by reference, in its entirety, into the present application.

### BACKGROUND OF THE INVENTION

### 1. Field of the Invention

The present invention relates to a method of manufacturing a conductive substrate, a conductive substrate, a touch sensor, an antenna, and an electromagnetic wave shielding material.

### 2. Description of the Related Art

A conductive film in which a patterned conductive layer is formed on a substrate is widely used in various fields of various sensors such as a pressure sensor or a biosensor, a print substrate, a solar cell, a capacitor, an electromagnetic wave shielding material, a touch panel, an antenna, and the like.

As a method of manufacturing the conductive film, for example, JP5356646B discloses “a method for forming a high-resolution pattern, the method including: a step (S1) of attaching a dry film resist to a substrate; a step (S2) of exposing and developing the attached dry film resist to light by irradiating the dry film resist with an energy beam to form a pattern template having a desired patterned recess portion; a step (S3) of filling the patterned recess portion with an ink including a functional material; and a step (S4) of drying the ink, in which a thickness (μm) of the dry film resist is represented by 100×β/α [where a represents a volume fraction (vol %) of the functional material in the ink, and β represents a thickness (μm) of the high-resolution pattern], and the pattern template and a unnecessary functional material remaining on the pattern template are removed after the step (S3). In addition, JP5356646B discloses an ink (conductive ink) including a conductive material as the ink including the functional material.

### SUMMARY OF THE INVENTION

The present inventors trial-manufactured a conductive substrate with reference to the method of forming the pattern described in JP5356646B and investigated the conductive substrate. As a result, it was clarified that, depending on the kind of the conductive ink to be used, it was clarified that, in the patterned conductive layer formed on the substrate, various defects such as disconnection, stripping from the substrate, short-circuiting in an opening portion, or foreign matter attachment may occur. That is, it was clarified that improvement for further reducing the frequency of the various defects that may occur in the conductive layer is required.

Accordingly, an object of the present invention is to provide a method of manufacturing a conductive substrate having a low defect ratio.

In addition, an object of the present invention is to provide a conductive substrate that is obtained using the method of manufacturing a conductive substrate.

In addition, another object of the present invention is to provide a touch sensor, an antenna, and an electromagnetic wave shielding material that include the conductive substrate.

As a result of thorough investigation to achieve the object, the present inventors found that the objects can be achieved with the following configurations.

[1] A method of manufacturing a conductive substrate including a substrate and a patterned conductive layer that is disposed on the substrate, the method comprising:

the following step X1, the following step X2, the following step X3, the following step X4, the following step X6, the following step X7, and the following step X8 in this order, in which in the step X4, a photosensitive resin layer is substantially insoluble in a conductive composition,

Step X1: a step of forming a photosensitive resin layer formed of a positive tone photosensitive resin composition on a substrate;

Step X2: a step of exposing the photosensitive resin layer in a patterned manner;

Step X3: a step of developing the exposed photosensitive resin layer with an alkali developer to form an opening portion that penetrates the photosensitive resin layer;

Step X4: a step of supplying a conductive composition to the opening portion in the photosensitive resin layer to form a conductive composition layer;

Step X6: a step of exposing the photosensitive resin layer in which the conductive composition layer is formed in the opening portion;

Step X7: a step of removing the exposed photosensitive resin layer using a stripper including water as a major component; and

Step X8: a step of sintering the conductive composition layer on the substrate by heating.

[2] The method of manufacturing a conductive substrate according to [1],

in which the conductive composition includes a solvent, and

a major component of the solvent is water.

[3] The method of manufacturing a conductive substrate according to [1] or [2], further comprising:

the following step X5 that is provided between the step X4 and the step X6,

in which a heating temperature in the step X5 is 50° C. or higher and lower than 120° C.,

Step X5: a step of drying the conductive composition layer by heating.

[4] The method of manufacturing a conductive substrate according to any one of [1] to [3],

in which the substrate is transparent, and

in the step X6, the photosensitive resin layer is exposed through the substrate from a surface of the substrate opposite to a side where the photosensitive resin layer is provided.

[5] The method of manufacturing a conductive substrate according to any one of [1] to [4],

in which the stripper further includes an organic amine.

[6] The method of manufacturing a conductive substrate according to [5],

in which a boiling point of the organic amine is 180° C. or lower.

[7] The method of manufacturing a conductive substrate according to [5] or [6],

in which in the step X8, the conductive composition layer is sintered at a temperature higher than a boiling point of the organic amine.

[8] The method of manufacturing a conductive substrate according to any one of [1] to [7],

in which a temperature of the stripper in the step X7 is lower than 50° C.

[9] The method of manufacturing a conductive substrate according to any one of [1] to [8],

in which the positive tone photosensitive resin composition includes a photoacid generator and a polymer having a polar group protected by a protective group that is deprotected by action of an acid.

[10] The method of manufacturing a conductive substrate according to [9],

in which the polar group protected by the protective group that is deprotected by action of the acid is an acetal group.

[11] The method of manufacturing a conductive substrate according to [9] or [10],

in which the polymer having the polar group protected by the protective group that is deprotected by action of the acid includes a constitutional unit represented by any one of Formulae A1 to A3 described below.

[12] The method of manufacturing a conductive substrate according to any one of [1] to [11],

in which the step X1 is a step of forming the photosensitive resin layer on the substrate using a photosensitive transfer member including a temporary support and the photosensitive resin layer disposed on the temporary support, and

the step X1 being a step of bonding the photosensitive transfer member and the substrate to each other by bringing a surface of the photosensitive resin layer opposite to the temporary support side into contact with the substrate.

[13] The method of manufacturing a conductive substrate according to any one of [1] to [12],

in which the conductive composition includes any of gold nanoparticles, silver nanoparticles, or copper nanoparticles.

[14] A conductive substrate that is formed using the method of manufacturing a conductive substrate according to any one of [1] to [13].

[15] A touch sensor comprising:

the conductive substrate according to [14].

[16] An antenna comprising:

the conductive substrate according to [14].

[17] An electromagnetic wave shielding material comprising:

the conductive substrate according to [14].

According to an aspect of the present invention, a method of manufacturing a conductive substrate having a low defect ratio can be provided.

In addition, according to another aspect of the present invention, a conductive substrate that is obtained using the method of manufacturing a conductive substrate can be provided.

In addition, according to still another aspect of the present invention, a touch sensor, an antenna, and an electromagnetic wave shielding material that include the conductive substrate can be provided.

### BRIEF DESCRIPTION OF THE DRAWINGS

FIG. 1 is a schematic diagram showing a conductive substrate 10 that is formed using a method of manufacturing a conductive substrate according to a first embodiment.

FIG. 2 is a schematic diagram showing a laminate 20 obtained through a step X1A.

FIG. 3 is a schematic diagram showing a step X2.

FIG. 4 is a schematic diagram showing a laminate 30 obtained through a step X3.

FIG. 5 is a schematic diagram showing a laminate 40 obtained through a step X4.

FIG. 6 is a schematic diagram showing the step X4.

FIG. 7 is a schematic diagram showing a step X6.

FIG. 8 is a schematic diagram showing a laminate 50 obtained through a step X7.

### DESCRIPTION OF THE PREFERRED EMBODIMENTS

Hereinafter, the content of the present invention will be described in detail. The following description regarding configuration requirements has been made based on a representative embodiment of the present invention. However, the present invention is not limited to the embodiment. The description will be made with reference to the accompanying drawings, and reference numerals may be omitted.

In the present specification, “to” representing a numerical range is used to represent a numerical range including numerical values before and after “to” as a lower limit value and an upper limit value.

In the present specification, unless specified as a substituted group or as an unsubstituted group, a group (atomic group) denotes not only a group having no substituent but also a group having a substituent. For example, “alkyl group” denotes not only an alkyl group having no substituent (unsubstituted alkyl group) but also an alkyl group having a substituent (substituted alkyl group).

In the present specification, “(meth)acrylic acid” is a concept including both of acrylic acid and methacrylic acid, “(meth)acrylate” is a concept including both of acrylate and methacrylate, and “(meth)acryloyl group” is a concept including both of an acryloyl group and a methacryloyl group.

In the present specification, the term “step” denotes not only an individual step but also a step which is not clearly distinguishable from another step as long as an effect expected from the step can be achieved.

In the present specification, unless specified otherwise, “exposure” denotes not only exposure using light but also drawing using a particle beam such as an electron beam or an ion beam. In addition, examples of the light generally used for the exposure include an actinic ray (active energy ray), for example, a bright light spectrum of a mercury lamp, a far ultraviolet ray represented by excimer laser, an extreme ultraviolet ray (EUV ray), or an X-ray.

Hereinafter, the present invention will be described.

[Method of Manufacturing Conductive Substrate]

A method of manufacturing a conductive substrate according to an embodiment of the present invention is

a method of manufacturing a conductive substrate including a substrate and a patterned conductive layer that is disposed on the substrate, the method comprising: the following step X1, the following step X2, the following step X3, the following step X4, the following step X6, the following step X7, and the following step X8 in this order, in which in the step X4, a photosensitive resin layer is substantially insoluble in a conductive composition.

Step X1: a step of forming a photosensitive resin layer formed of a positive tone photosensitive resin composition on a substrate

Step X2: a step of exposing the photosensitive resin layer in a patterned manner

Step X3: a step of developing the exposed photosensitive resin layer with an alkali developer to form an opening portion that penetrates the photosensitive resin layer

Step X4: a step of supplying a conductive composition to the opening portion in the photosensitive resin layer to form a conductive composition layer

Step X6: a step of exposing the photosensitive resin layer in which the conductive composition layer is formed in the opening portion

Step X7: a step of removing the exposed photosensitive resin layer using a stripper including water as a major component

Step X8: a step of sintering the conductive composition layer on the substrate by heating

In addition, it is preferable that the manufacturing method further includes, between the step X4 and the step X6, a step of drying the conductive composition layer obtained in the step X4. It is preferable that the step of drying the conductive composition layer obtained in the step X4 is the following step X5.

Step X5: a step of drying the conductive composition layer by heating

The conductive substrate obtained using the method of manufacturing a conductive substrate having the above-described configuration has a low defect ratio. In the patterned conductive layer formed on the substrate, the occurrence of various defects such as disconnection, stripping from the substrate, short-circuiting in an opening portion, or foreign matter attachment is suppressed.

The action mechanism between the configuration and the effect is presumed to be as follows.

According to a recent investigation, the present inventors presumed that the above-described various defects occur main in the stripping treatment in the step X7 due to excessive bonding between the conductive composition and the photosensitive resin layer that functions as a mold for supplying the conductive composition. On the other hand, in the method of manufacturing a conductive substrate according to the embodiment of the present invention, the bonding is suppressed by using that conductive composition that is substantially insoluble in the photosensitive resin layer in the step X4. As a result, it is presumed that the defect ratio in the stripping treatment is reduced.

Hereinafter, regarding the method of manufacturing the conductive substrate according to the embodiment of the present invention, each of the steps will be described in detail with reference to the drawings. In addition, the conductive substrate will also be described in detail together with the description of the method of manufacturing the conductive substrate according to the embodiment of the present invention.

The following description regarding configuration requirements has been made based on a representative embodiment of the present invention. However, the present invention is not limited to the embodiment.

### First Embodiment

A first embodiment of the method of manufacturing the conductive substrate includes the following step X1A, the following step X2, the following step X3, the following step X4, the following step X5, the following step X6, the following step X7, and the following step X8 in this order.

Step X1A: a step of forming a photosensitive resin layer on a substrate using a photosensitive transfer member including a temporary support and a photosensitive resin layer disposed on the temporary support, the photosensitive resin layer being formed of a positive tone photosensitive resin composition

Step X2: a step of exposing the photosensitive resin layer in a patterned manner

Step X3: a step of developing the exposed photosensitive resin layer with an alkali developer to form an opening portion that penetrates the photosensitive resin layer

Step X4: a step of supplying a conductive composition to the opening portion in the photosensitive resin layer to form a conductive composition layer

Step X5: a step of drying the conductive composition layer by heating Step X6: a step of exposing the photosensitive resin layer in which the conductive composition layer is formed in the opening portion

Step X7: a step of removing the exposed photosensitive resin layer using a stripper including water as a major component

Step X8: a step of sintering the conductive composition layer on the substrate by heating

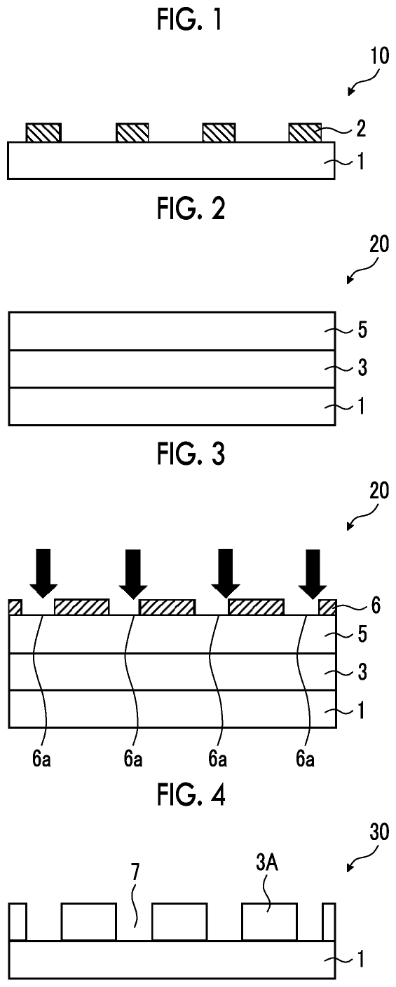

FIG. 1 is a schematic diagram showing a conductive substrate 10 that is formed using the first embodiment of the method of manufacturing the conductive substrate. The conductive substrate 10 includes: a substrate 1; and a patterned conductive layer 2 disposed on the substrate 1.

From the viewpoint of reducing the defect ratio of the formed conductive substrate, the thickness of the patterned conductive layer 2 is preferably 5.0 μm or less and more preferably 3.0 μm or less. The lower limit value is, for example, 0.1 μm or more and preferably 0.2 μm or more.

Materials used in each of the steps and a procedure thereof will be described in detail with reference to the drawings.

<<Step X1A>>

The step X1A is a step of forming a photosensitive resin layer on a substrate using a photosensitive transfer member including a temporary support and a photosensitive resin layer disposed on the temporary support, the photosensitive resin layer being formed of a positive tone photosensitive resin composition.

Hereinafter, the materials used in the step X1A will be described, and then the procedure thereof will be described.

<Positive Tone Photosensitive Resin Composition>

Hereinafter, the positive tone photosensitive resin composition will be described.

The positive tone photosensitive resin composition may be a chemically amplified positive tone photosensitive resin composition or may be a non-chemically amplified positive tone photosensitive resin composition. From the viewpoint of further improving the sensitivity during the exposure, it is preferable that the positive tone photosensitive resin composition is a chemically amplified photosensitive resin composition.

The chemically amplified positive tone photosensitive resin composition is not particularly limited, and a well-known positive tone photosensitive resin composition can be applied. From the viewpoint of further improving sensitivity, resolution, and removability, it is preferable that the chemically amplified positive tone photosensitive resin composition is a composition including a photoacid generator and a polymer (hereinafter, also referred to as “acid-decomposable resin”) having a polar group (hereinafter, also referred to as “acid-decomposable group”) protected by a protective group that is deprotected by action of an acid.

The acid-decomposable resin is not particularly limited as long as it is a resin where a part of a molecular structure is decomposable by action of an acid, and examples thereof include a polymer that includes a constitutional unit having an acid-decomposable group.

In a case where the photoacid generator such as an onium salt or an oxime sulfonate compound described below is used, an acid that is produced in response to a radioactive ray (hereinafter, also referred to as “actinic ray” acts as a catalyst in the deprotection reaction of the acid-decomposable group in the acid-decomposable resin. An acid that is produced by action of one photon contributes to a large number of deprotection reactions. Therefore, the quantum yield exceeds 1, for example, a large value such as a multiple of 10, and high sensitivity is obtained as a result of so-called chemical amplification. On the other hand, in a case where a quinone diazide compound is used as the photoacid generator that is reactive with a radioactive ray, a carboxy group is produced due to a sequential photochemical reaction. However, the quantum yield of the carboxy group is inevitably 1 or less, and the carboxy group does not correspond to a chemical amplification type.

(Acid-Decomposable Resin)

The positive tone photosensitive resin composition includes a polymer (acid-decomposable resin) having a polar group (acid-decomposable group) protected by a protective group that is deprotected by action of an acid.

It is preferable that the acid-decomposable resin is a polymer (hereinafter, also referred to as “polymer A”) having a constitutional unit (hereinafter, also referred to as “constitutional unit A”) having an acid-decomposable group.

Hereinafter, the polymer A will be described.

<<Polymer A>>

The polymer A includes the constitutional unit (constitutional unit A) having an acid-decomposable group.

The acid-decomposable group is converted into a polar group that is deprotected by action of an acid produced during exposure. Accordingly, the solubility of the photosensitive resin layer formed of the positive tone photosensitive resin composition in an alkali developer increases during exposure.

The polymer A is preferably an addition polymerization type resin and more preferably a polymer including a constitutional unit derived from (meth)acrylic acid or a (meth)acrylate.

The polymer A may include a constitutional unit (for example, a constitutional unit derived from styrene or a constitutional unit derived from a vinyl compound) other than the constitutional unit derived from (meth)acrylic acid or a (meth)acrylate.

Hereinafter, the constitutional units that can be included in the polymer A will be described.

Constitutional Unit a (Constitutional Unit Having Acid-Decomposable Group)

The polymer A includes the constitutional unit having an acid-decomposable group. As described above, the acid-decomposable group can be converted into a polar group by action of an acid.

In the present specification, “polar group” refers to a proton dissociable group having a pKa of 12 or less.

Examples of the polar group include a well-known acid group such as a carboxy group or a phenolic hydroxy group. In particular, it is preferable that the polar group is a carboxy group or a phenolic hydroxy group.

The protective group is not particularly limited, and examples thereof include a well-known protective group.

Examples of the protective group include a protective group that can protect a polar group in the form of acetal (for example, a tetrahydropyranyl group, a tetrahydrofuranyl group, or an ethoxyethyl group) and a protective group that can protect a polar group in the form of ester (for example, a tert-butyl group).

As the acid-decomposable group, for example, a group that is likely to be decomposed by an acid (for example, an acetal functional group such as an ester group, a tetrahydropyranyl ester group, or a tetrahydrofuranyl ester group in a constitutional unit represented by Formula A3 described below) or a group that is not likely to be decomposed by an acid (for example, a tertiary alkyl ester group such as a tert-butyl ester group or a tertiary alkyl carbonate group such as a tert-butyl carbonate group) can be used.

In particular, it is preferable that the acid-decomposable group is a group in which a carboxy group or a phenolic hydroxy group is protected in the form of acetal.

From the viewpoint of further improving sensitivity and resolution, as the constitutional unit A, one or more constitutional units selected from the group consisting of a constitutional unit represented by Formula A1, a constitutional unit represented by Formula A2, and a constitutional unit represented by Formula A3 are preferable, one or more constitutional units selected from the group consisting of the constitutional unit represented by Formula A1 and the constitutional unit represented by Formula A3 are more preferable, and one or more constitutional units selected from the group consisting of a constitutional unit represented by Formula A1-2 and a constitutional unit represented by Formula A3-3 are still more preferable.

The constitutional unit represented by Formula A1 and the constitutional unit represented by Formula A2 are constitutional units having an acid-decomposable group in which a phenolic hydroxy group is protected by a protective group that is deprotected by action of an acid. The constitutional unit represented by Formula A3 is a constitutional unit having an acid-decomposable group in which a carboxy group is protected by a protective group that is deprotected by action of an acid.

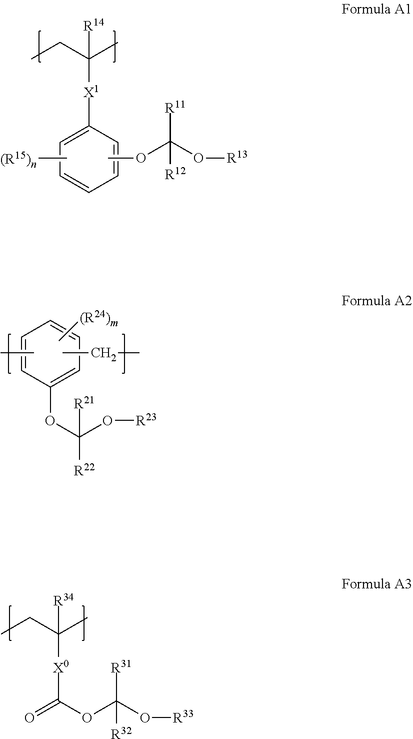

In Formula A1, R¹¹ and R¹² each independently represent a hydrogen atom, an alkyl group, or an aryl group. At least one of R¹¹ or R¹² represents an alkyl group or an aryl group. R¹³ represents an alkyl group or an aryl group. R¹⁴ represents a hydrogen atom or a methyl group. X¹ represents a single bond or a divalent linking group. R¹⁵ represents a substituent. n represents an integer of 0 to 4. R¹¹ or R¹² and R¹³ may be linked to each other to form a cyclic ether (in a case where one of R¹¹ or R¹² is linked to R¹³ to form a cyclic ether, the other one of R¹¹ or R¹² may represent a hydrogen atom, that is, the other one of R¹¹ or R¹² does not need to represent an alkyl group or an aryl group).

In Formula A2, R²¹ and R²² each independently represent a hydrogen atom, an alkyl group, or an aryl group. At least one of R²¹ or R²² represents an alkyl group or an aryl group. R²³ represents an alkyl group or an aryl group. R²⁴'s each independently represent a hydroxy group, a halogen atom, an alkyl group, an alkoxy group, an alkenyl group, an aryl group, an aralkyl group, an alkoxycarbonyl group, a hydroxyalkyl group, an arylcarbonyl group, an aryloxycarbonyl group, or a cycloalkyl group. m represents an integer of 0 to 3. R²¹ or R²² and R²³ may be linked to each other to form a cyclic ether (in a case where one of R²¹ or R²² is linked to R²³ to form a cyclic ether, the other one of R²¹ or R²² may represent a hydrogen atom, that is, the other one of R²¹ or R²² does not need to represent an alkyl group or an aryl group).

In Formula A3, R³¹ and R³² each independently represent a hydrogen atom, an alkyl group, or an aryl group. At least one of R³¹ or R³² represents an alkyl group or an aryl group. R³³ represents an alkyl group or an aryl group. R³⁴ represents a hydrogen atom or a methyl group. X⁰ represents a single bond or a divalent linking group. R³¹ or R³² and R³³ may be linked to each other to form a cyclic ether (in a case where one of R³¹ or R³² is linked to R³³ to form a cyclic ether, the other one of R³¹ or R³² may represent a hydrogen atom, that is, the other one of R³¹ or R³² does not need to represent an alkyl group or an aryl group).

—Preferable Aspect of Constitutional Unit represented by Formula A1—

In Formula A1, the number of carbon atoms in the alkyl group represented by R¹¹ and R¹² is preferably 1 to 10. As the aryl group represented by R¹¹ and R¹², a phenyl group is preferable.

As R¹¹ and R¹², in particular, a hydrogen atom or an alkyl group having 1 to 4 carbon atoms is preferable.

The alkyl group or the aryl group represented by R¹³ in Formula A1 is the same as the alkyl group or the aryl group represented by R¹¹ and R¹². As R¹³, in particular, an alkyl group having 1 to 10 carbon atoms is preferable, and an alkyl group having 1 to 6 carbon atoms is more preferable.

In Formula A1, the alkyl group and the aryl group in R¹¹, R¹², and R¹³ may further have a substituent.

It is preferable that R¹¹ or R¹² and R¹³ in Formula A1 are linked to each other to form a cyclic ether. The number of members in the cyclic ether is preferably 5 or 6 and more preferably 5.

It is preferable that X¹ in Formula A1 represents a single bond or a divalent linking group including a combination of one or more kinds selected from the group consisting of an alkylene group, —C(═O)O—, —C(═O)NR^{N}—, and —O—, and it is more preferable that X¹ represents a single bond.

The alkylene group may be linear, branched, or cyclic and may further have a substituent. The number of carbon atoms in the alkylene group is preferably 1 to 10 and more preferably 1 to 4.

In a case where X¹ represents —C(═O)O—, it is preferable that a carbon atom in —C(═O)O— and a carbon atom bonded to R¹⁴ are directly bonded to each other.

In addition, in a case where X¹ represents —C(═O)NR^{N}—, it is preferable that a carbon atom in —C(═O)NR^{N}— and a carbon atom bonded to R¹⁴ are directly bonded to each other.

R^{N} represents an alkyl group or a hydrogen atom, preferably an alkyl group having 1 to 4 carbon atoms or a hydrogen atom, and more preferably a hydrogen atom.

In Formula A1, it is preferable that the group represented by —OC(R¹¹)(R¹²)—OR¹³ and X¹ are bonded to each other at the para position on the benzene ring represented by the formula from the viewpoint of steric hindrance of the acid-decomposable group. That is, it is preferable that the constitutional unit represented by Formula A1 is a constitutional unit represented by Formula A1-1.

R¹¹, R¹², R¹³, R¹⁴, R¹⁵, X¹, and n in Formula A1-1 have the same definitions as R¹¹, R¹², R¹³, R¹⁴, R¹⁵, X¹, and n in Formula A1, respectively.

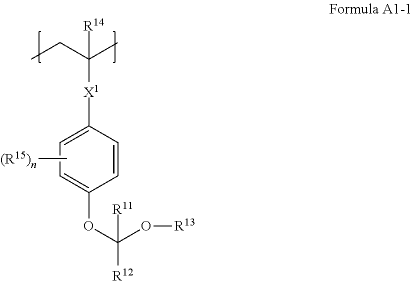

It is preferable that R¹⁵ in Formula A1 represent an alkyl group or a halogen atom. The number of carbon atoms in the alkyl group is preferably 1 to 10 and more preferably 1 to 4.

In Formula A1, n represents preferably 0 or 1 and more preferably 0.

From the viewpoint of further reducing the glass transition temperature (Tg) of the polymer A, it is preferable that R¹⁴ in Formula A1 represents a hydrogen atom.

More specifically, the content of the constitutional unit in which R¹⁴ in Formula A1 represents a hydrogen atom is preferably 20 mass % or more with respect to the total content of the constitutional unit A in the polymer A. The content of the constitutional unit in which R¹⁴ in Formula A1 represents a hydrogen atom in the constitutional unit A can be verified from an intensity ratio between peak intensities calculated using a routine method by ¹³C-nuclear magnetic resonance spectrum (NMR).

Among the constitutional units represented by Formula A1, a constitutional unit represented by Formula A1-2 is more preferable from the viewpoint of further suppressing deformation of a pattern shape.

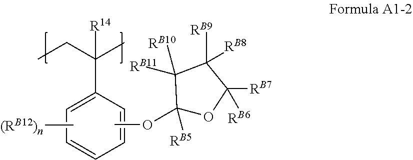

In Formula A1-2, R^{B4} represents a hydrogen atom or a methyl group. R^{B5} to R^{B11} each independently represent a hydrogen atom or an alkyl group having 1 to 4 carbon atoms. R^{B12} represents a substituent. n represents an integer of 0 to 4.

In Formula A1-2, it is preferable that R^{B4} represents a hydrogen atom.

In Formula A1-2, it is preferable that R^{B5} to R^{B11} represent a hydrogen atom.

It is preferable that R^{B12} in Formula A1-2 represents an alkyl group or a halogen atom. The number of carbon atoms in the alkyl group is preferably 1 to 10 and more preferably 1 to 4.

In Formula A1-2, n represents preferably 0 or 1 and more preferably 0.

In Formula A1-2, it is preferable that a group including R^{B5} to R^{B11} and a carbon atom bonded to R^{B4} are bonded to each other at the para position on the benzene ring represented by the formula from the viewpoint of steric hindrance of the acid-decomposable group.

Specific preferable examples of the constitutional unit represented by Formula A1 include the following constitutional units. R^{B4} in the following constitutional units represents a hydrogen atom or a methyl group.

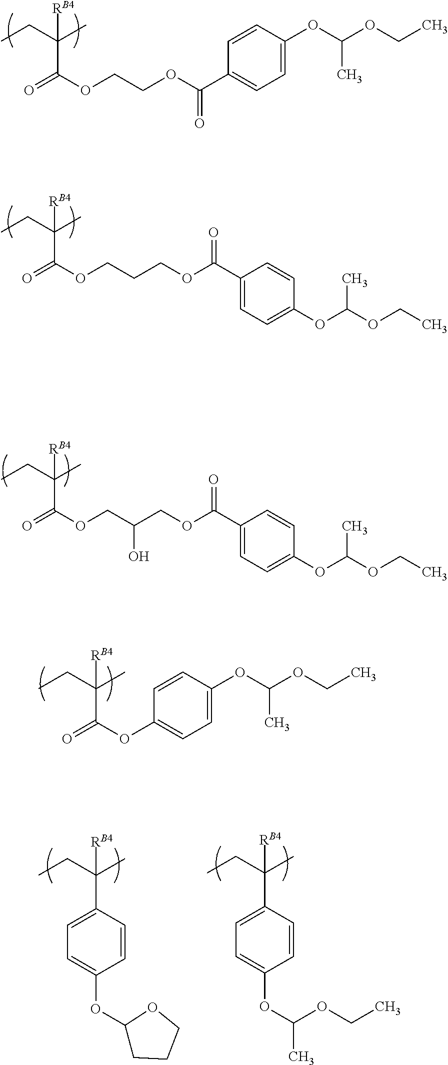

—Preferable Aspect of Constitutional Unit Represented by Formula A2—

In Formula A2, the number of carbon atoms in the alkyl group represented by R²¹ and R²² is preferably 1 to 10. As the aryl group represented by R²¹ and R²², a phenyl group is preferable.

In particular, it is preferable that R²¹ and R²² represents a hydrogen atom or an alkyl group having 1 to 4 carbon atoms, and it is more preferable that at least one of R²¹ or R²² represents a hydrogen atom.

The alkyl group or the aryl group represented by R²³ in Formula A2 is the same as the alkyl group or the aryl group represented by R²¹ and R²². As R²³, in particular, an alkyl group having 1 to 10 carbon atoms is preferable, and an alkyl group having 1 to 6 carbon atoms is more preferable.

In Formula A2, the alkyl group and the aryl group in R²¹, R²², and R²³ may further have a substituent.

In Formula A2, R²⁴ each independently represent preferably an alkyl group having 1 to 10 carbon atoms or an alkoxy group having 1 to 10 carbon atoms and more preferably an alkyl group having 1 to 4 carbon atoms. R²⁴ may further have a substituent. Examples of the substituent include an alkyl group having 1 to 10 carbon atoms and an alkoxy group having 1 to 10 carbon atoms.

In Formula A2, m represents preferably 1 or 2 and more preferably 1.

Specific preferable examples of the constitutional unit represented by Formula A2 include the following constitutional units.

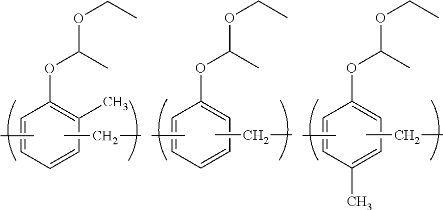

—Preferable Aspect of Constitutional Unit represented by Formula A3—

In Formula A3, the number of carbon atoms in the alkyl group represented by R³¹ and R³² is preferably 1 to 10. As the aryl group represented by R³¹ and R³², a phenyl group is preferable.

As R³¹ and R³², in particular, a hydrogen atom or an alkyl group having 1 to 4 carbon atoms is preferable.

As R³³ in Formula A3, in particular, an alkyl group having 1 to 10 carbon atoms is preferable, and an alkyl group having 1 to 6 carbon atoms is more preferable.

The alkyl group and the aryl group in R³¹ to R³³ may further have a substituent.

It is preferable that R³¹ or R³² and R³³ in Formula A3 are linked to each other to form a cyclic ether. The number of members in the cyclic ether is preferably 5 or 6 and more preferably 5.

In Formula A3, X⁰ represents preferably a single bond or an arylene group and more preferably a single bond. The arylene group may further have a substituent.

From the viewpoint of further reducing the glass transition temperature (Tg) of the polymer A, it is preferable that R³⁴ in Formula A3 represents a hydrogen atom.

More specifically, the content of a constitutional unit in which R³⁴ in Formula A3 represents a hydrogen atom is preferably 20 mass % or more with respect to the total content of the constitutional unit represented by Formula A3 in the polymer A.

The content of the constitutional unit in which R³⁴ in Formula A3 represents a hydrogen atom in the constitutional unit represented by Formula A3 can be verified from an intensity ratio between peak intensities calculated using a routine method by ¹³C-nuclear magnetic resonance spectrum (NMR).

Among the constitutional units represented by Formula A3, a constitutional unit represented by Formula A3-3 is more preferable from the viewpoint of further improving the sensitivity during pattern formation.

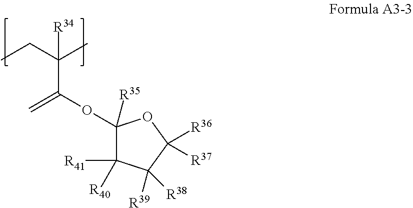

In Formula A3-3, R³⁴ represents a hydrogen atom or a methyl group. R³⁵ to R⁴¹ each independently represent a hydrogen atom or an alkyl group having 1 to 4 carbon atoms.

In Formula A3-3, it is preferable that R³⁴ represents a hydrogen atom.

In Formula A3-3, it is preferable that R³⁵ to R⁴¹ represent a hydrogen atom.

Specific preferable examples of the constitutional unit represented by Formula A3 include the following constitutional units.

R³⁴ in the following constitutional units represents a hydrogen atom or a methyl group.

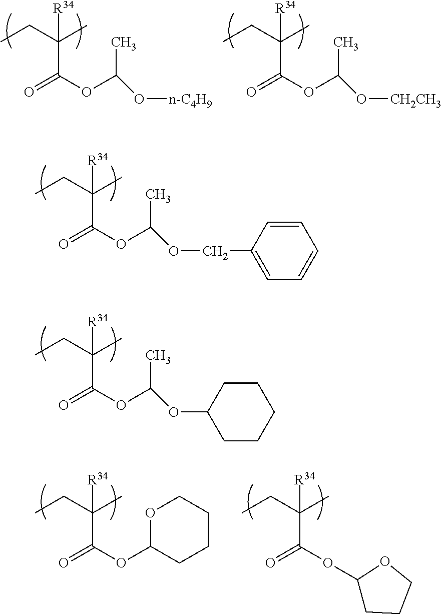

The constitutional units A in the polymer A may be used alone or in combination of two or more kinds.

The content of the constitutional unit A in the polymer A is preferably 20 mass % or more, more preferably 20 to 90 mass %, and still more preferably 20 to 70 mass % with respect to the total mass of the polymer A.

The content of the constitutional unit A in the polymer A can be verified from an intensity ratio between peak intensities calculated using a routine method by ¹³C-NMR.

Constitutional Unit B (Constitutional Unit Having Polar Group)

It is preferable that the polymer A includes a constitutional unit (hereinafter, also referred to as “constitutional unit B”) having a polar group. In a case where the polymer A includes the constitutional unit B, the sensitivity during pattern formation is improved, and the solubility in the alkali developer in the development step after pattern exposure is improved.

The polar group in the constitutional unit B is a proton dissociable group having a pKa of 12 or less.

From the viewpoint of further improving the sensitivity, the upper limit value of the pKa of the polar group is preferably 10 or less and more preferably 6 or less. In addition, it is preferable that the lower limit value is −5 or more.

Examples of the polar group in the constitutional unit B include a carboxy group, a sulfonamide group, a phosphonate group, a sulfonate group, a phenolic hydroxy group, and a sulfonylimide group. In particular, it is preferable that the polar group is a carboxy group or a phenolic hydroxy group.

Examples of a method of introducing the constitutional unit B into the polymer A include a method of copolymerizing a monomer having a polar group and a method of copolymerizing a monomer having an acid anhydride structure and hydrolyzing the acid anhydride. Examples of the monomer having a carboxy group as the polar group include acrylic acid, methacrylic acid, itaconic acid, crotonic acid, maleic acid, fumaric acid, and 4-carboxystyrene. In addition, examples of the monomer having a phenolic hydroxy group as the polar group include p-hydroxystyrene and 4-hydroxyphenyl methacrylate. In addition, examples of the monomer having an acid anhydride structure include maleic acid anhydride.

As the constitutional unit B, a constitutional unit derived from a styrene compound having a polar group or a constitutional unit derived from a vinyl compound having a polar group is preferable, a constitutional unit derived from a styrene compound having a phenolic hydroxy group or a constitutional unit derived from a vinyl compound having a carboxy group is preferable, a constitutional unit derived from a vinyl compound having a carboxy group is still more preferable, and a constitutional unit derived from (meth)acrylic acid) is still more preferable.

The constitutional units B may be used alone or in combination of two or more kinds.

The content of the constitutional unit B in the polymer A is preferably 0.1 to 20 mass %, more preferably 0.5 to 15 mass %, and still more preferably 1 to 10 mass % with respect to the total mass of the polymer A. By adjusting the content of the constitutional unit B in the polymer A to be in the above-described numerical range, pattern formability is further improved.

The content of the constitutional unit B in the polymer A can be verified from an intensity ratio between peak intensities calculated using a routine method by ¹³C-NMR.

Constitutional Unit C (Other Constitutional Units)

The polymer A may further include constitutional units (hereinafter, also referred to as “constitutional unit C”) other than the constitutional unit A and the constitutional unit B. By adjusting at least one of the kind or the content of the constitutional unit C in the polymer A, various properties of the polymer A can be adjusted. In particular, by appropriately using the constitutional unit C, the glass transition temperature (Tg) of the polymer A can be easily adjusted.

Examples of a monomer forming the constitutional unit C include a styrene, an alkyl (meth)acrylate, a cyclic alkyl (meth)acrylate, an aryl (meth)acrylate, an unsaturated dicarboxylic acid diester, a bicyclo unsaturated compound, a maleimide compound, an unsaturated aromatic compound, a conjugated diene compound, an unsaturated monocarboxylic acid, an unsaturated dicarboxylic acid, an unsaturated dicarboxylic anhydride, an unsaturated compound having an aliphatic cyclic skeleton, and other well-known unsaturated compounds.

Examples of the constitutional unit C include constitutional units derived from styrene, tert-butoxystyrene, methylstyrene, α-methylstyrene, acetoxystyrene, methoxystyrene, ethoxystyrene, chlorostyrene, methyl vinylbenzoate, ethyl vinylbenzoate, methyl (meth)acrylate, ethyl (meth)acrylate, n-propyl (meth)acrylate, isopropyl (meth)acrylate, 2-hydroxyethyl (meth)acrylate, 2-hydroxypropyl (meth)acrylate, benzyl (meth)acrylate, isobornyl (meth)acrylate, acrylonitrile, and ethylene glycol monoacetate acetate mono(meth)acrylate. Other examples of the constitutional unit C include constitutional units derived from compounds described in paragraphs “0021” to “0024” of JP2004-264623A.

From the viewpoint of further improving electrical properties, it is preferable that the constitutional unit C is a constitutional unit having an aromatic ring or a constitutional unit having an aliphatic cyclic skeleton.

Examples of a monomer forming the constitutional unit include styrene, tert-butoxystyrene, methylstyrene, α-methylstyrene, dicyclopentanyl (meth)acrylate, cyclohexyl (meth)acrylate, isobornyl (meth)acrylate, and benzyl (meth)acrylate. In particular, it is preferable that the constitutional unit C is a constitutional unit derived from cyclohexyl (meth)acrylate.

In a case where the step X1 is performed by transfer as described below, from the viewpoint of further improving adhesion, the constitutional unit C is preferably an alkyl (meth)acrylate and more preferably an alkyl (meth)acrylate that has an alkyl group having 4 to 12 carbon atoms.

Specific examples of the constitutional unit C include methyl (meth)acrylate, ethyl (meth)acrylate, propyl (meth)acrylate, n-butyl (meth)acrylate, and 2-ethylhexyl (meth)acrylate.

From the viewpoint of further improving the solubility in the developer and/or from the viewpoint of optimizing physical properties, it is also preferable that the polymer A includes, as the constitutional unit C, a constitutional unit having an ester of a polar group in the constitutional unit B. In particular, it is preferable that the polymer A includes a constitutional unit having a carboxy group as the constitutional unit B and further includes the constitutional unit C having a carboxylate group, and it is more preferable that the polymer A includes, for example, the constitutional unit B derived from (meth)acrylic acid and further includes the constitutional unit C derived from a monomer selected from the group consisting of cyclohexyl (meth)acrylate, 2-ethylhexyl (meth)acrylate, and n-butyl (meth)acrylate.

The constitutional units C may be used alone or in combination of two or more kinds.

The upper limit value of the content of the constitutional unit C in the polymer A is preferably 80 mass % or less, more preferably 75 mass % or less, still more preferably 60 mass % or less, and still more preferably 50 mass % or less with respect to the total mass of the polymer A. The lower limit value of the content of the constitutional unit C in the polymer A may be 0 mass % and is preferably 1 mass % or more and more preferably 5 mass % or more with respect to all of the constitutional units forming the polymer A. By adjusting the content of the constitutional unit C in the polymer A to be in the above-described numerical range, the resolution and the adhesion can be further improved.

Hereinafter, preferable examples of the polymer A will be shown, but the present invention is not limited thereto. A ratio between constitutional units in each of the following exemplary compounds and a weight-average molecular weight thereof are appropriately selected in order to obtain preferable physical properties.

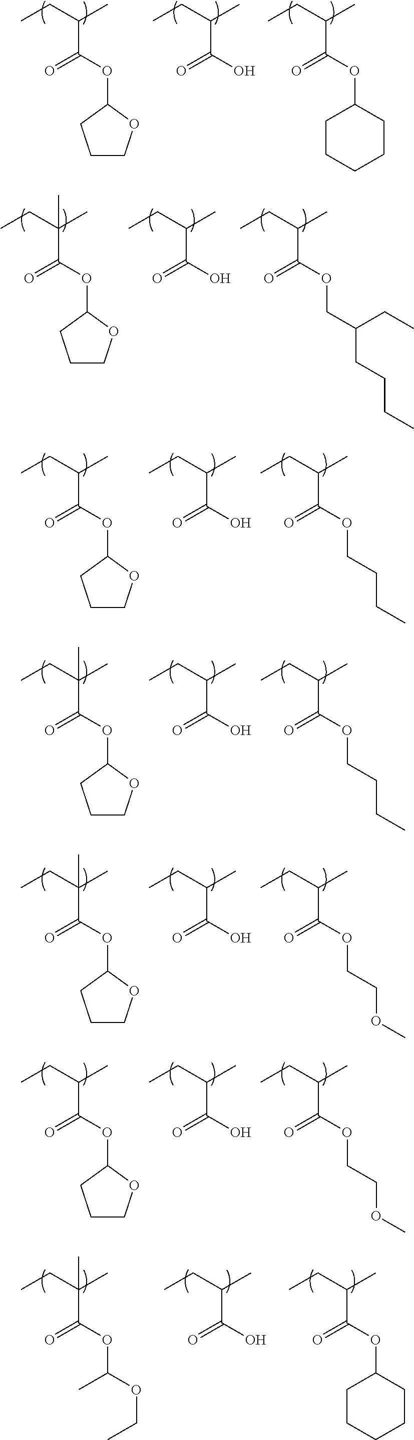

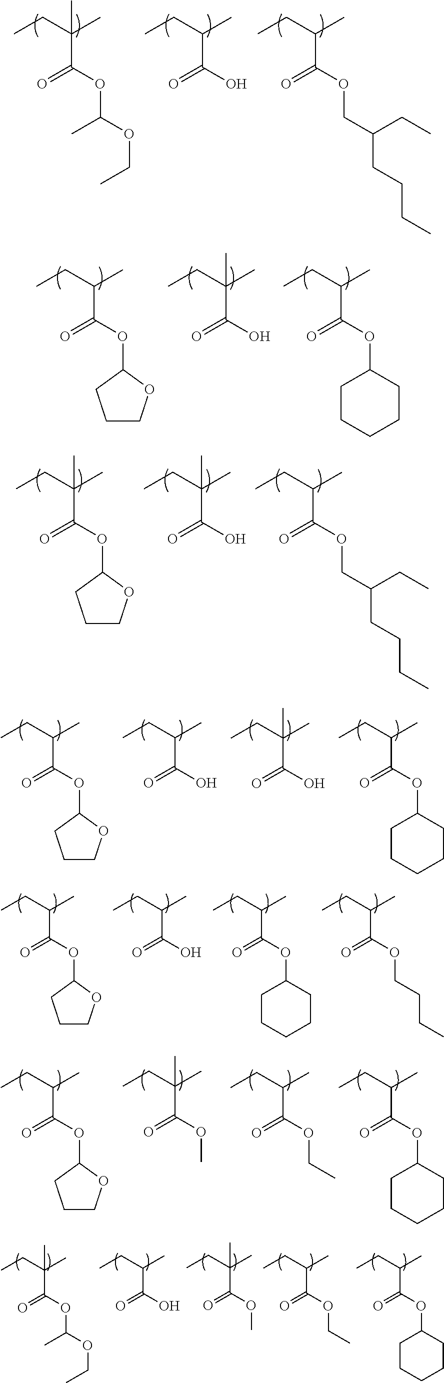

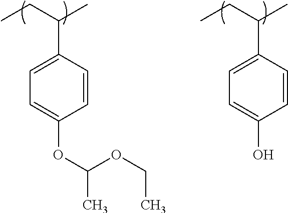

The polymers A may be used alone or in combination of two or more kinds.

The content of the polymer A in the positive tone photosensitive resin composition is preferably 50 to 99.9 mass % and more preferably 70 to 98 mass % with respect to the total solid content of the composition.

Glass Transition Temperature of Polymer A (Tg)

In a case where the step X1 is performed by transfer as described below, from the viewpoint of transfer properties, the glass transition temperature (Tg) of the polymer A is preferably 90° C. or lower, more preferably 20° C. to 60° C., and still more preferably 30° C. to 50° C.

Examples of a method of adjusting the glass transition temperature (Tg) of the polymer A to be in the above-described numerical range include a method of adjusting the kind and the mass fraction of each of the constitutional units in the polymer A by using the FOX equation as a guide. The glass transition temperature (Tg) of the polymer A can be adjusted by adjusting the glass transition temperature (Tg) of a homopolymer of each of the constitutional units in the polymer A and the mass fraction of each of the constitutional units using the FOX equation. In addition, the glass transition temperature (Tg) of the polymer A can be adjusted by adjusting the weight-average molecular weight of the polymer A.

Hereinafter, the FOX equation will be described using a copolymer including a first constitutional unit and a second constitutional unit.

In a case where a glass transition temperature of a homopolymer of the first constitutional unit is represented by Tg1, a mass fraction of the first constitutional unit in the copolymer is represented by W1, a glass transition temperature of a homopolymer of the second constitutional unit is represented by Tg2, and a mass fraction of the second constitutional unit in the copolymer is represented by W2, Tg0 (unit: K) of the copolymer including the first constitutional unit and the second constitutional unit can be estimated based on the following equation. Accordingly, by adjusting the kind and the mass fraction of each of constitutional units in a desired polymer using the FOX equation, a polymer having a desired glass transition temperature (Tg) can be obtained.

1/Tg0=(W1/Tg1)+(W2/Tg2) FOX Equation:

Acid Value of Polymer A

From the viewpoint of resolution ability, the acid value of the polymer A is preferably 0 to 200 mgKOH/g and more preferably 0 to 100 mgKOH/g.

The acid value of the polymer represents the mass of potassium hydroxide required for neutralizing an acidic component per 1 g of the polymer. Specifically, a measurement sample is dissolved in a mixed solvent including tetrahydrofuran and water at a ratio (volume ratio; tetrahydrofuran/water) of 9/1, and the obtained solution is neutralized and titrated with a 0.1 mol/L sodium hydroxide aqueous solution at 25° C. using a potentiometric titrator (trade name: AT-510, manufactured by Kyoto Electronics Manufacturing Co., Ltd.). An inflection point of a titration pH curve is set as a titration end point, and the acid value was calculated from the following expression.

Expression A=56.11×Vs×0.1×f/w

A: the acid value (mgKOH/g)

Vs: the amount (mL) of the 0.1 mol/L sodium hydroxide aqueous solution used for the titration

f: the titer of the 0.1 mol/L sodium hydroxide aqueous solution

w: the mass (g) of the measurement sample (expressed in terms of solid contents)

Molecular Weight: Polymer A (Mw)

The weight-average molecular weight (Mw) of the polymer A is preferably 2,000 to 60,000 and more preferably 3,000 to 50,000.

The weight-average molecular weight (Mw) of the polymer A can be measured by gel permeation chromatography (GPC), and various commercially available devices can be used as a measuring device.

In the measurement of the weight-average molecular weight by gel permeation chromatography (GPC), HLC (registered trade name)-8220GPC (manufactured by Tosoh Corporation) can be used as a measuring device, a column in which TSKgel (registered trade name) Super HZM-M (4.6 mm ID×15 cm, manufactured by Tosoh Corporation), Super HZ4000 (4.6 mm ID×15 cm, manufactured by Tosoh Corporation), Super HZ3000 (4.6 mm ID×15 cm, manufactured by Tosoh Corporation), and Super HZ2000 (4.6 mm ID×15 cm, manufactured by Tosoh Corporation) are linked in series one by one can be used as a column, and tetrahydrofuran (THF) can be used as an eluent.

In addition, the measurement can be used using a differential refractive index (RI) detector under measurement conditions of sample concentration: 0.2 mass %, flow rate: 0.35 ml/min, sample injection volume: 10 μL, and measurement temperature: 40° C.

A calibration curve can be obtained from 7 samples of “Standard sample, TSK standard, polystyrene”: “F-40”, “F-20”, “F-4”, “F-1”, “A-5000”, “A-2500”, and “A-1000” (manufactured by Tosoh Corporation).

A ratio (dispersity) between the number-average molecular weight and the weight-average molecular weight of the polymer A is preferably 1.0 to 5.0 and more preferably 1.05 to 3.5.

Method of Manufacturing Polymer A

A method (synthesis method) of manufacturing the polymer A is not particularly limited. For example, the polymer A can be synthesized by polymerizing a polymerizable monomer for forming the constitutional unit A and a polymerizable monomer for forming the constitutional unit B, and optionally a polymerizable monomer for forming the constitutional unit C in an organic solvent using a polymerization initiator. In addition, the polymer A can also be synthesized in a so-called polymer reaction.

(Other Polymers)

In addition to the polymer A, the positive tone photosensitive resin composition may further include a polymer (hereinafter, also referred to as “other polymer”) that does not include a constitutional unit having an acid-decomposable group.

Examples of the other polymer include polyhydroxystyrene. Examples of a commercially available product that can be used as the polyhydroxystyrene include: SMA 1000P, SMA 2000P, SMA 3000P, SMA 1440F, SMA 17352P, SMA 2625P, and SMA 3840f (all of which are manufactured by Sartomer); ARUFON UC-3000, ARUFON UC-3510, ARUFON UC-3900, ARUFON UC-3910, ARUFON UC-3920, ARUFON UC-3080 (all of which are manufactured by Toagosei Co., Ltd.); and Joncryl 690, Joncryl 678, Joncryl 67, and Joncryl 586 (manufactured by BASF SE).

The other polymers may be used alone or in combination of two or more kinds.

In a case where the positive tone photosensitive resin composition includes the other polymer, the content of the other polymer in the positive tone photosensitive resin composition is preferably 50 mass % or less, more preferably 30 mass % or less, and still more preferably 20 mass % or less with respect to the total content of the polymer A and the other polymer.

(Photoacid Generator)

It is preferable that the positive tone photosensitive resin composition includes a photoacid generator. The photoacid generator is a compound that produces an acid by irradiation of radiation such as an ultraviolet ray, a far ultraviolet ray, an X-ray, or a charged particle beam.

As the photoacid generator, a compound that produces an acid in response to an actinic ray having a wavelength of 300 nm or more and preferably a wavelength of 300 to 450 nm is preferable. From the viewpoint of further improving the spectral sensitivity, in particular, a compound having absorption at a wavelength of 365 nm is more preferable as the photoacid generator.

In addition, a photoacid generator that is not directly reactive with an actinic ray having a wavelength of 300 nm or more can be preferably used in combination with a sensitizer as long as it is a compound that produces an acid in response to an actinic ray having a wavelength of 300 nm or more by being used in combination with a sensitizer.

The photoacid generator is preferably a photoacid generator that produces an acid having a pKa of 4 or less, more preferably a photoacid generator that produces an acid having a pKa of 3 or less, and still more preferably a photoacid generator that produces an acid having a pKa of 2 or less. The lower limit value of the pKa of the acid produced from the photoacid generator is not particularly limited and, for example, is preferably −10 or more.

Examples of the photoacid generator include an ionic photoacid generator and a nonionic photoacid generator. In addition, from the viewpoint of further improving sensitivity and resolution, it is preferable that the photoacid generator includes one or more kinds selected from the group consisting of an onium salt compound and an oxime sulfonate compound, and it is preferable that the photoacid generator includes an oxime sulfonate compound.

Examples of the ionic photoacid generator include an onium salt compound such as a diaryl iodonium salt or a triarylsulfonium salt and a quaternary ammonium salt. In particular, as the ionic photoacid generator, an onium salt compound is preferable, and a diaryl iodonium salt or a triarylsulfonium salt is more preferable.

As the ionic photoacid generator, an ionic photoacid generator described in paragraphs “0114” to “0133” of JP2014-85643A can be preferably used.

Examples of the nonionic photoacid generator include a trichloromethyl-s-triazine, a diazomethane compound, an imide sulfonate compound, and an oxime sulfonate compound. In particular, from the viewpoint of improving the sensitivity, the resolution, and the adhesion, an oxime sulfonate compound is preferable as the nonionic photoacid generator. Specific examples of the trichloromethyl-s-triazine and a diazomethane compound include compounds described in paragraphs “0083” to “0088” of JP2011-221494A.

As the oxime sulfonate compound, that is, the compound having an oxime sulfonate structure, a compound having an oxime sulfonate structure represented by Formula (B1) is preferable.

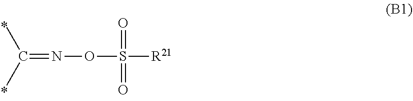

In Formula (B1), R²¹ represents an alkyl group or an aryl group, and * represents a bonding site to another atom or another group.

The compound having an oxime sulfonate structure represented by Formula (B1) may be substituted with any group, and the alkyl group in R21 may be linear, branched, or cyclic. A substituent that is allowed will be described below.

As the alkyl group represented by R²¹, a linear or branched alkyl group having 1 to 10 carbon atoms is preferable. The alkyl group represented by R^{2′} may be substituted with an awl group having 6 to 11 carbon atoms, an alkoxy group having 1 to 10 carbon atoms, a cycloalkyl group (for example, including a bridged alicyclic group such as a 7,7-dimethyl-2-oxonorbornyl group; a bicycloalkyl group), or a halogen atom.

As the aryl group in R²¹, an aryl group having 6 to 18 carbon atoms is preferable, and a phenyl group or a naphthyl group is more preferable. The aryl group in R²¹ may be substituted with one or more groups selected from the group consisting of an alkyl group having 1 to 4 carbon atoms, an alkoxy group, and a halogen atom.

It is preferable that the compound having an oxime sulfonate structure represented by Formula (B1) is an oxime sulfonate compound described in paragraphs “0078” to “0111” of JP2014-85643A.

The photoacid generators may be used alone or in combination with two or more kinds.

From the viewpoint of further improving the sensitivity and the resolution, the content of the photoacid generator in the positive tone photosensitive resin composition is preferably 0.1 to 10 mass % and more preferably 0.2 to 5 mass % with respect to the total mass of the composition.

(Solvent)

The positive tone photosensitive resin composition may include a solvent.

Examples of the solvent include an ethylene glycol monoalkyl ether, an ethylene glycol dialkyl ether, an ethylene glycol monoalkyl ether acetate, a propylene glycol monoalkyl ether, a propylene glycol dialkyl ether, a propylene glycol monoalkyl ether acetate, a diethylene glycol dialkyl ether, a diethylene glycol monoalkyl ether acetate, a dipropylene glycol monoalkyl ether, a dipropylene glycol dialkyl ether, a dipropylene glycol monoalkyl ether acetate, an ester, a ketone, an amide, and a lactone. In addition, as the solvent, for example, solvents described in paragraphs “0174” to “0178” of JP2011-221494A can also be used, the contents of which are incorporated herein by reference.

In addition to the above-described solvents, optionally, the positive tone photosensitive resin composition may further include a solvent such as benzyl ethyl ether, dihexyl ether, ethylene glycol monophenyl ether acetate, diethylene glycol monomethyl ether, diethylene glycol monoethyl ether, isophorone, caproic acid, caprylic acid, 1-octanol, 1-nonanol, benzyl alcohol, anisole, benzyl acetate, ethyl benzoate, diethyl oxalate, diethyl maleate, ethylene carbonate, or propylene carbonate.

As the solvent, a solvent having a boiling point of 130° C. or higher and lower than 160° C., a solvent having a boiling point of 160° C. or higher, or a mixture thereof is preferable.

Examples of the solvent having a boiling point of 130° C. or higher and lower than 160° C. include propylene glycol monomethyl ether acetate (boiling point: 146° C.), propylene glycol monoethyl ether acetate (boiling point: 158° C.), propylene glycol methyl-n-butyl ether (boiling point: 155° C.), and propylene glycol methyl-n-propyl ether (boiling point: 131° C.).

Examples of the solvent having a boiling point of 160° C. or higher include ethyl 3-ethoxypropionate (boiling point: 170° C.), diethylene glycol methyl ethyl ether (boiling point: 176° C.), propylene glycol monomethyl ether propionate (boiling point: 160° C.), dipropylene glycol methyl ether acetate (boiling point: 213° C.), 3-methoxy butyl ether acetate (boiling point: 171° C.), diethylene glycol diethyl ether (boiling point: 189° C.), diethylene glycol dimethyl ether (boiling point: 162° C.), propylene glycol diacetate (boiling point: 190° C.), diethylene glycol monoethyl ether acetate (boiling point: 220° C.), dipropylene glycol dimethyl ether (boiling point: 175° C.), and 1,3-butylene glycol diacetate (boiling point: 232° C.).

In addition, preferable examples of the solvent include an ester, an ether, and a ketone.

Examples of the ester include ethyl acetate, propyl acetate, isobutyl acetate, sec-butyl acetate, t-butyl acetate, isopropyl acetate, and n-butyl acetate.

Examples of the ether include diisopropyl ether, 1,4-dioxane, 1,2-dimethoxyethane, 1,3-dioxolane, propylene glycol dimethyl ether, and propylene glycol monoethyl ether.

Examples of the ketone include methyl n-butyl ketone, methyl ethyl ketone, methyl isobutyl ketone, diethyl ketone, methyl n-propyl ketone, and methyl isopropyl ketone.

In addition, as the solvent, for example, toluene, acetonitrile, isopropanol, 2-butanol, or isobutyl alcohol may be used.

The solvents may be used alone or in combination with two or more kinds.

The content of the solvent in the positive tone photosensitive resin composition is preferably 50 to 1,900 parts by mass and more preferably 100 to 900 parts by mass with respect to 100 parts by mass of the total solid content of the composition.

(Other Additives)

In addition to the polymer A and the photoacid generator, optionally, the positive tone photosensitive resin composition may further include other additives.

Basic Compound

It is preferable that the positive tone photosensitive resin composition includes a basic compound. Examples of the basic compound include a quaternary ammonium salt such as aliphatic amine, aromatic amine, heterocyclic amine, quaternary ammonium hydroxide, and carboxylic acid. Specific examples of the basic compound include compounds described in paragraphs “0204” to “0207” of JP2011-221494A, the contents of which are incorporated herein by reference.

Examples of the aliphatic amine include trimethylamine, diethylamine, triethylamine, di-n-propylamine, tri-n-propylamine, di-n-pentylamine, tri-n-pentylamine, diethanolamine, triethanolamine, dicyclohexylamine, and dicyclohexylmethylamine.

Examples of the aromatic amine include aniline, benzylamine, N,N-dimethylaniline, and diphenylamine

Examples of the heterocyclic amine include pyridine, 2-methylpyridine, 4-methylpyridine, 2-ethylpyridine, 4-ethylpyridine, 2-phenylpyridine, 4-phenylpyridine, N-methyl-4-phenylpyridine, 4-dimethylaminopyridine, imidazole, benzimidazole, 4-methylimidazole, 2-phenylbenzimidazole, 2,4,5-triphenylimidazole, nicotine, nicotinic acid, nicotinic acid amide, quinoline, 8-oxyquinoline, pyrazine, pyrazole, pyridazine, purine, pyrrolidine, piperidine, piperazine, morpholine, 4-methylmorpholine, 1,5-diazabicyclo[4.3.0]-5-nonene, 1,8-diazabicyclo-[5.3.0]-7-undecene, N-cyclohexyl-N′-[2-(4-morpholinyl)ethyl]thiourea, and 1,2,3-benzotriazole.

Examples of the quaternary ammonium hydroxide include tetramethylammonium hydroxide, tetraethylammonium hydroxide, tetra-n-butyl ammonium hydroxide, and tetra-n-hexyl ammonium hydroxide.

Examples of a quaternary ammonium salt of carboxylic acid include tetramethylammonium acetate, tetramethylammonium, benzoate, tetra-n-butyl ammonium acetate, and tetra-n-butyl ammonium benzoate.

The basic compounds may be used alone or in combination with two or more kinds.

The content of the basic compound in the positive tone photosensitive resin composition is preferably 0.001 to 5 mass % and more preferably 0.005 to 3 mass % with respect to the total mass of the composition.

Liquid Repellent

From the viewpoint of further improving the uniformity of the thickness and the viewpoint of further reducing the defect ratio of the conductive substrate to be formed, it is preferable that the positive tone photosensitive resin composition includes a liquid repellent.

As the liquid repellent, a compound including one or more kinds of fluorine atoms and one or more kinds of silicon atoms is preferable, a fluorine atom-containing compound is more preferable, a fluorine atom-containing surfactant is still more preferable, and a fluorine atom-containing nonionic surfactant is still more preferable.

In addition, as the liquid repellent, a liquid repellent having a polymerizable group (hereinafter, also referred to as “polymerizable group-containing liquid repellent”) can also be used. Examples of the polymerizable group include an epoxy group and an ethylenically unsaturated group.

In addition, as the liquid repellent, a compound represented by Formula (1) disclosed in JP2013-209636A can also be used.

As the fluorine atom-containing compound, as described above, a fluorine atom-containing nonionic surfactant is preferable. Preferable examples of the fluorine atom-containing nonionic surfactant include a copolymer including a constitutional unit SA and a constitutional unit SB represented by Formula I-1, in which a weight-average molecular weight (Mw) in terms of polystyrene measured by gel permeation chromatography in a case where tetrahydrofuran (THF) is used as a solvent is 1,000 to 10,000.

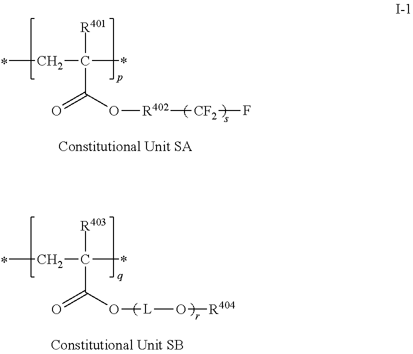

In Formula I-1, R⁴⁰¹ and R⁴⁰³ each independently represent a hydrogen atom or a methyl group. R⁴⁰² represents a linear alkylene group having 1 to 4 carbon atoms. R⁴⁰⁴ represents a hydrogen atom or an alkyl group having 1 to 4 carbon atoms. L represents an alkylene group having 3 to 6 carbon atoms. p and q represent a mass percentage representing a weight ratio. p represents a numerical value of 10 to 80 mass %, and q represents a numerical value of 20 to 90 mass %. r represents an integer of 1 to 18. s represents an integer of 1 to 10. * represents a bonding site to another structure.

It is preferable that L represents a branched alkylene group represented by Formula I-2.

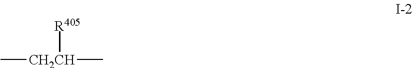

R⁴⁰⁵ in Formula I-2 represents an alkyl group having 1 to 4 carbon atoms. From the viewpoint of compatibility and wettability on a coating surface, an alkyl group having 1 to 3 carbon atoms is preferable, and an alkyl group having 2 or 3 carbon atoms is more preferable.

It is preferable that (p+q) as the sum of p and q in Formula I-1 satisfies p+q=100, that is, is 100 mass %.

The weight-average molecular weight (Mw) of the copolymer including the constitutional unit SA and the constitutional unit SB represented by Formula I-1 is preferably 1,500 to 5,000.

Hereinafter, other specific examples of the liquid repellent other than the above-described copolymer will be shown.

Examples of the fluorine atom-containing compound include perfluoroalkylsulfonic acid, perfluoroalkylcarboxylic acid, a perfluoroalkylalkylene oxide adduct, a perfluoroalkyltrialkylammonium salt, an oligomer including a perfluoroalkyl group a hydrophilic group, an oligomer including a perfluoroalkyl group and a lipophilic group, an oligomer including a perfluoroalkyl group, a hydrophilic group, and a lipophilic group, an urethane including perfluoroalkyl group and a hydrophilic group, perfluoroalkyl ester, and perfluoroalkyl phosphoric acid ester.

Examples of a commercially available product that can be used as the fluorine atom-containing compound include: “DEFENSAMCF-300”, “DEFENSAMCF-310”, “DEFENSAMCF-312”, “DEFENSAMCF-323”, and “MEGAFACE RS-72-K (all of which are manufactured by DIC Corporation); “FLUORAD FC-431”, “FLUORAD FC-4430”, and “FLUORAD FC-4432” (all of which are manufactured by 3M); “ASAHI GUARD AG710”, “SURFLON S-382”, “SURFLON SC-101”, “SURFLON SC-102”, “SURFLON SC-103”, “SURFLON SC-104”, “SURFLON SC-105”, and “SURFLON SC-106” (all of which are manufactured by Asahi Glass Co., Ltd.); and “OPTOOL DAC-HP” and “HP-650” (both of which are manufactured by Daikin Industries, Ltd.).

In addition, other examples of a commercially available product that can be used as the fluorine atom-containing compound include “MEGAFACE” series manufactured by DIC Corporation, for example, F-251, F-253, F-281, F-430, F-477, F-551, F-552, F-553, F-554, F-555, F-556, F-557, F-558, F-559, F-560, F-561, F-562, F-563, F-565, F-568, F-569, F-570, F-572, F-574, F-575, F-576, F-780, EXP, MFS-330, MFS-578, MFS-579, MFS-586, MFS-587, R-40, R-40-LM, R-41, RS-43, TF-1956, RS-90, R-94, RS-72-K, and DS-21 (a fluorine atom-containing surfactant having an oligomer structure).

In addition, other examples of a commercially available product that can be used as the fluorine atom-containing compound include: FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); PolyFox PF636, PF656, PF6320, PF6520, and PF7002 (all of which are manufactured by OMNOVA Solutions Inc.); and FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS Co., Ltd.).

In addition, as a commercially available product that can be used as the fluorine atom-containing compound, a fluorine atom-containing nonionic surfactant such as FTERGENT 250 or FTERGENT 251 manufactured by NEOS Co., Ltd. can also be used.

In addition, as the fluorine atom-containing compound, a surfactant described in paragraph “0017” of JP4502784B or paragraphs “0060” to “0071” of JP2009-237362A can also be used.

From the viewpoint of improving environmental aptitude, it is preferable that the fluorine-based surfactant is a surfactant derived from an alternative material of a compound that has a linear perfluoroalkyl group having 7 or more carbon atoms, for example, perfluorooctanoic acid (PFOA) or perfluorooctanesulfonic acid (PFOS).

Examples of a commercially available product of a silicon atom-containing compound include a silicone-based surfactant such as SILFOAM (registered trade name) series manufactured by Wacker Chemie AG (for example, SD100TS, SD670, SD850, SD860, or SD882).

The liquid repellents may be used alone or in combination of two or more kinds.

In a case where a fluorine atom-containing compound is used as the liquid repellent, the lower limit value of the content of the fluorine atom in the liquid repellent is preferably 1 mass % or more and more preferably 5 mass % or more. The upper limit value is preferably 50 mass % or less and more preferably 25 mass % or less.

The content of the liquid repellent in the positive tone photosensitive resin composition is, for example, 0.01 to 10 mass % and preferably 0.05 to 5 mass % with respect to the total solid content of the composition.

Surfactant

From the viewpoint of further improving the uniformity of the thickness, it is preferable that the positive tone photosensitive resin composition includes a surfactant. The surfactant described herein does not include the above-described surfactant-based liquid repellent.

As the surfactant, any of an anionic surfactant, a cationic surfactant, a nonionic surfactant, or an amphoteric surfactant can also be used. In particular, a nonionic surfactant is preferable.

Examples of the nonionic surfactant include a polyoxyethylene higher alkyl ether, a polyoxyethylene higher alkyl phenyl ether, and a higher fatty acid diester of polyethylene glycol. Specific examples of the nonionic surfactant include a nonionic surfactant described in paragraph “0120” of WO2018/179640A.

The surfactants may be used alone or in combination with two or more kinds.

The content of the surfactant in the positive tone photosensitive resin composition is preferably 10 mass % or less, more preferably 0.001 to 10 mass %, and still more preferably 0.01 to 3 mass % with respect to the total mass of the composition.

Plasticizer

In order to improve plasticity, the positive tone photosensitive resin composition may include a plasticizer. The plasticizer is not particularly limited, and a well-known plasticizer can be applied. Examples of the plasticizer include plasticizers described in paragraphs “0097” to “0103” of WO2018/179640A.

Sensitizer

The positive tone photosensitive resin composition may include a sensitizer. The sensitizer is not particularly limited, and a well-known sensitizer can be applied. Examples of the sensitizer include sensitizers described in paragraphs “0104” to “0107” of WO2018/179640A.

Heterocyclic Compound

The positive tone photosensitive resin composition may include a heterocyclic compound. The heterocyclic compound is not particularly limited, and a well-known heterocyclic compound can be applied. Examples of the heterocyclic compound include heterocyclic compounds described in paragraphs “0111” to “0118” of WO2018/179640A.

Alkoxysilane Compound

The positive tone photosensitive resin composition may include an alkoxysilane compound. The alkoxysilane compound is not particularly limited, and a well-known alkoxysilane compound can be applied. The alkoxysilane compound is not particularly limited, and examples thereof include alkoxysilane compounds described in paragraph “0119” of WO2018/179640A.

Other Components

The positive tone photosensitive resin composition may further include other additives such as metal oxide particles, an antioxidant, a dispersant, an acid proliferation agent, a development accelerator, conductive fibers, a colorant, a thermal radical polymerization initiator, a thermal acid generator, an ultraviolet absorber, a thickener, a crosslinking agent, or an organic or inorganic suspending agent. Preferable aspects of the other components are described in paragraphs “0165” to “0184” of JP2014-85643, the content of which is incorporated herein by reference.

(Method of Preparing Composition)

Examples of a method of preparing the positive tone photosensitive resin composition include a method of mixing the above-described components and the solvent at an arbitrary ratio and stirring and dissolving the solution. In addition, the positive tone photosensitive resin composition can be prepared by dissolving each of the above-described components in a solvent to prepare a solution and mixing the obtained solutions with each other at a predetermined ratio. The prepared positive tone photosensitive resin composition may be used after being filtered through a filter or the like having a pore diameter of 0.2 μm.

<Photosensitive Transfer Member>

The photosensitive transfer member includes: a temporary support; and a photosensitive resin layer that is disposed on the temporary support, the photosensitive resin layer being formed of the above-described positive tone photosensitive resin composition. In addition, the photosensitive transfer member may include a protective film that is provided on a surface of the photosensitive resin layer opposite to the temporary support.

Examples of the temporary support include a glass substrate and a resin film.

The temporary support may have a monolayer structure consisting of a single layer or may have a multi-layer structure including two or more layers.

The thickness of the temporary support is not particularly limited and is, for example, 6 to 150 μm and preferably 12 to 50 μm.

The photosensitive transfer member includes the photosensitive resin layer that is provided on the temporary support and is formed of the above-described positive tone photosensitive resin composition.

From the viewpoint of transfer properties and resolution ability, the lower limit value of the thickness of the photosensitive resin layer is preferably 1.0 μm or more. The upper limit value is, for example, 30.0 μm or less, preferably 15.0 μm or less, more preferably 10.0 μm or less, and still more preferably 5.0 μm or less.

Examples of a method of forming the photosensitive resin layer include a method including: applying the positive tone photosensitive resin composition to the temporary support to form a coating film; and drying the coating film.

Examples of an application method include a well-known method such as slit coating, spin coating, curtain coating, or ink jet coating.

The drying temperature is not particularly limited and is, for example, 80° C. to 150° C. In addition, the drying time is not particularly limited and is, for example, 3 to 60 minutes.

Another layer such as an interlayer may be provided on the temporary support. In a case where another layer such as an interlayer is disposed on the temporary support, the photosensitive resin layer is formed on the other layer.

Examples of the other layer include layers described in paragraphs “0131” to “0134” of WO2018/179640A.

<Substrate>

The substrate is not particularly limited, and a glass substrate or a resin substrate is preferable and a resin substrate is more preferable.

Examples of a resin forming the resin substrate include a resin such as polycarbonate (PC), an acrylonitrile/butadiene/styrene copolymer (ABS resin), an acrylonitrile/styrene copolymer (AS), polypropylene (PP), polyethylene (PE), polyamide (PA), polyacetal (POM), polybutylene terephthalate (PBT), polyethylene terephthalate (PET), polyphenylene sulfide (PPS), polyether ether ketone (PEEK), polystyrene (PS), polymethyl methacrylate (PMMA), polyphenylene ether (PPE), polysulfone (PSF), polyether sulfone (PES), polyamide imide (PAT), polyether imide (PEI), polyimide (PI), or polyvinyl chloride (PVC).

In order to improve adhesion with the conductive layer, a surface treatment such as a hydrophilization treatment may be performed on the surface of the substrate.

From the viewpoint of easily exposing the photosensitive resin layer through the substrate from the surface (back surface of the substrate) of the substrate opposite to the side where the photosensitive resin layer is provided in the step X6, it is preferable that the substrate is transparent. It is preferable that a transmittance of the substrate with respect to light in a visible range of 400 to 700 nm is 50% or more, and it is more referable that a transmittance of the substrate with respect to light in a wavelength range of 400 to 450 nm is more than 10%.

The thickness of the substrate is preferably 10 to 200 μm, more preferably 20 to 150 μm, and still more preferably 30 to 100 μm.

<Procedure of Step X1A>

In the step X1A, the substrate and the photosensitive transfer member are bonded to each other by bringing the surface of the photosensitive resin layer opposite to the temporary support into contact with the substrate. In a case where a protective film is provided on the surface of the photosensitive resin layer opposite to the temporary support, the substrate and the photosensitive transfer member are bonded to each other after removing the protective film from the photosensitive transfer member.

In order to bond the substrate and the photosensitive transfer member to each other, a well-known laminator such as a laminator, a vacuum laminator, or an auto cut laminator that can further improve productivity can be used. In a case where the substrate and the photosensitive transfer member are bonded to each other, it is preferable that the photosensitive transfer member is laminated on the substrate and is pressurized and heated using a roll or the like.

By performing the step X1A, a laminate 20 shown in FIG. 2 is obtained. The laminate 20 includes: a substrate 1; and a photosensitive resin layer 3 and a temporary support 5 provided on the substrate 1.

<<Step X2>>

The step X2 is a step of exposing the photosensitive resin layer 3 of the laminate 20 obtained through the step X1 in a patterned manner.

FIG. 3 schematically shows an example of the exposure step.

In the step X2, a mask 6 having an opening portion 6a is disposed to be closely attached to the temporary support 5, and the photosensitive resin layer 3 of the laminate 20 is exposed in a patterned manner through the temporary support 5.

By performing the step X2, in the acid-decomposable resin in the exposed portion (position corresponding to the opening portion 6a) of the photosensitive resin layer 3, the acid-decomposable group is deprotected by action of an acid, and the solubility in the alkali developer increases. By performing the step X2, the exposed portion of the photosensitive resin layer 3 is removed in the development step of the following step X3.

The position and the size of the opening portion of the mask are not particularly limited. For example, in a case where a display device (for example a touch panel) or the like including an input device having a circuit wiring is manufactured, from the viewpoints of improving the display quality of the display device and reducing the area of the lead-out wiring line, the shape of the opening portion is a fine linear shape, and the width thereof is preferably 100 μm or less and more preferably 70 μm or less.

As the light source used for the exposure, any light source can be appropriately selected and used as long as it can emit light in a wavelength range (for example, 365 nm or 405 nm) with which the photosensitive resin layer can be exposed. Specific examples of the light source include an ultrahigh pressure mercury lamp, a high-pressure mercury lamp, a metal halide lamp, and a light emitting diode (LED). In particular, from the viewpoint of the spectral sensitivity of the photosensitive resin layer, it is preferable to emit light having a wavelength of 365 nm.

The exposure amount is preferably 5 to 1000 mJ/cm², more preferably 100 to 1000 mJ/cm², and still more preferably 100 to 500 mJ/cm².

In the step X2, the exposure treatment may be performed after stripping the temporary support 5 from the photosensitive resin layer 3. In addition, the pattern exposure may be exposure through a mask or direct exposure using a laser or the like.

<<Step X3>>

The step X3 is a step of developing the photosensitive resin layer that is exposed in a patterned manner in the step X2 with an alkali developer to form an opening portion that penetrates the photosensitive resin layer. The temporary support 5 is stripped from the laminate 20 before performing the step X3.

As shown in FIG. 4, the laminate 30 obtained through the development treatment of the step X3 includes: the substrate 1; and a photosensitive resin layer 3A that is disposed on the substrate 1 and has an opening portion 7 penetrating the photosensitive resin layer 3A. That is, the photosensitive resin layer 3A has the opening portion 7 from which the substrate 1 is exposed. The position of the opening portion 7 penetrating the photosensitive resin layer 3A matches with the position of the opening portion (the opening portion 6a in FIG. 3) of the mask pattern used during the exposure treatment of the step X2. That is, the photosensitive resin layer 3A has the opening portion 7 at the position corresponding to the opening portion 6a of the mask used during the exposure treatment of the step X2.

In the step X4 described below, the conductive composition is supplied to the opening portion 7.

It is preferable that the alkali developer is an alkali aqueous solution developer containing a compound having a pKa of 7 to 13 is 0.05 to 5 mol/L (liter). The alkali aqueous solution developer may further include a water-soluble organic solvent and a surfactant.

As the alkali aqueous solution developer, a developer described in paragraph “0194” of WO2015/093271A is preferable.

A development method is not particularly limited and may be any of puddle development, shower development, spin development, dip development, or the like. Here, shower development will be described. The exposed portion can be removed by blowing the alkali developer to the exposed photosensitive resin layer by showering. In addition, it is preferable to remove a development residue by blowing a cleaning agent by showering while rubbing the exposed portion with a brush or the like. The liquid temperature of the alkali developer is preferably 20 to 40° C.

The step X3 may further include a post-baking step of heating the developed photosensitive resin layer.

The post-baking is performed preferably in an environment of 8.1 to 121.6 kPa and more preferably in an environment of 50.66 kPa or more. On the other hand, the post-baking is performed preferably in an environment of 111.46 kPa or less and more preferably in an environment of 101.3 kPa or less.

The temperature of post-baking is preferably 80° C. to 250° C., more preferably 110° C. to 170° C., and still more preferably 130° C. to 150° C.

The time of post-baking is preferably 1 to 30 minutes, more preferably 2 to 10 minutes, and still more preferably 2 to 4 minutes.

The post-baking may be performed in an air environment or in a nitrogen purged environment.

<<Step X4>>

The step X4 is a step of supplying the conductive composition to the opening portion 7 in the photosensitive resin layer 3A of the laminate 30 shown in FIG. 4.

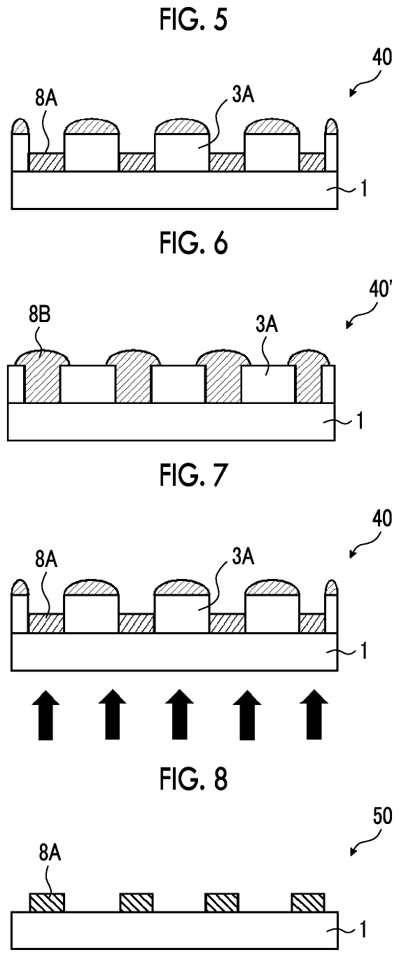

FIG. 5 shows a laminate 40 obtained through the step X4. The laminate 40 includes a conductive composition layer 8A that is formed of the conductive composition in the opening portion 7 of the photosensitive resin layer 3A. In the step of supplying the conductive composition to the opening portion 7 in the photosensitive resin layer 3A, the conductive composition may be attached to a region (for example, an upper surface of the photosensitive resin layer 3A) other than the opening portion 7 as shown in FIG. 5. Accordingly, as a method of supplying the conductive composition, a method of applying the conductive composition to the entire surface of the photosensitive resin layer 3A may be adopted.

In the step X4, as the conductive composition, a composition in which the photosensitive resin layer is substantially insoluble is used. That is, in the step X4, the photosensitive resin layer is substantially insoluble in the conductive composition. Whether or not the conductive composition is a composition in which the photosensitive resin layer is substantially insoluble is determined using the following method.

(Preparation of Test Substrate and Measurement of Thickness)

The positive tone photosensitive resin composition used in the step X1 is applied to the surface of the substrate to form a coating film such that the dry thickness is 3 μm. Next, by drying the coating film by hot air at 90° C. for 0.5 hours, a test substrate where the photosensitive resin layer is formed on the substrate is prepared. As the substrate, a polyethylene terephthalate film is preferable.

Next, the thickness of the photosensitive resin layer in the test substrate is measured. Specifically, using scanning electron microscopy (SEM), a cross section including a direction perpendicular to a main surface of the layer is observed, the thickness of the layer is measured at 10 or more points based on the obtained observation image, and an average value T1 (μm) is calculated.

(Dipping Treatment)

The above-described test substrate is dipped in the conductive composition (temperature: 30° C.) used in the step X4 for 5 minutes. After being dipped for a predetermined time, the test substrate is extracted from the conductive composition and is dried at 90° C.

(Measurement of Thickness of Test Substrate after Dipping Treatment)

Next, the thickness of the photosensitive resin layer in the test substrate after the dipping treatment is measured. Specifically, a cross section including a direction perpendicular to a main surface of the layer is observed using a SEM, the thickness of the layer is measured at 10 or more points based on the obtained observation image, and an average value T2 (μm) is calculated.

(Determination)

In a case where a value (F) calculated from Expression (1) is 95% or more, it is determined that the conductive composition is a composition in which the photosensitive resin layer is substantially insoluble. That is, in a case where a change in the thickness of the photosensitive resin layer after the dipping treatment is 5% or less, it is determined that the conductive composition is a composition in which the photosensitive resin layer is substantially insoluble.

F=(T2/T1)×100 Expression (1):

Further, it is preferable that a contact angle of the surface of the photosensitive resin layer 3A with respect to the conductive composition is more than a contact angle of the surface of the substrate 1 with respect to the conductive composition. That is, it is preferable that the wettability of the conductive composition on the surface of the substrate 1 is higher than that on the surface of the photosensitive resin layer 3A.

In a case where the contact angle of the surface of the photosensitive resin layer 3A with respect to the conductive composition is less than the contact angle of the surface of the substrate 1 with respect to the conductive composition, as shown in FIG. 6, the conductive composition supplied to the opening portion 7 of the photosensitive resin layer 3A may move up a side surface of the photosensitive resin layer 3A to bleed out to the upper surface of the photosensitive resin layer 3A (refer to a conductive composition layer 8B of FIG. 6). As a result, defects such as short-circuit tend to occur in the conductive layer 2 of the formed conductive substrate. Therefore, as described above, it is preferable that the contact angle of the surface of the photosensitive resin layer 3A with respect to the conductive composition is more than the contact angle of the surface of the substrate 1 with respect to the conductive composition. In addition, in a case where the wettability of the conductive composition on the substrate 1 is excellent, uneven distribution of the conductive composition in the opening portion 7 is suppressed, and the film thickness uniformity of the conductive layer obtained through a sintering step of the step X8 described below is further improved.

In particular, it is preferable that the surface of the photosensitive resin layer 3A has liquid repellency (repelling properties) with respect to the conductive composition, and it is preferable that the surface of the substrate 1 has lyophilicity with respect to the conductive composition.

The liquid repellency and the lyophilicity with respect to the conductive composition can be evaluated using the following method.

Liquid droplets of the conductive composition are dropped on an object to be evaluated, and the behavior of the liquid droplets are evaluated. In a case where the surface area of the liquid droplets decreases with respect to the amount of liquid droplets during dropping, the object to be evaluated has liquid repellency. On the other hand, in a case where the surface area of the liquid droplets increases with respect to the amount of liquid droplets during dropping, the object to be evaluated has lyophilicity.

It is preferable that the liquid repellency of the surface of the photosensitive resin layer 3A is higher, and it is preferable that the lyophilicity of the substrate 1 is higher. From the viewpoint that the defect ratio of the formed conductive substrate can be further reduced, the contact angle of the conductive composition with respect to the surface of the photosensitive resin layer 3A is preferably 30° or more, and the contact angle of the conductive composition with respect to the surface of the substrate 1 is preferably less than 30°.

Examples of a method of improving the liquid repellency of the conductive composition with respect to the surface of the photosensitive resin layer 3A to deteriorate wettability include a method of mixing the liquid repellent in the positive tone photosensitive resin composition.

Hereinafter, the materials used in the step X4 will be described, and then the procedure thereof will be described.

<Conductive Composition>

As the conductive composition, a conductive material is included.

The conductive material refers to not only a material that exhibits conductivity by itself but also a material that can form a conductive layer after being sintered.

As the conductive material, a conductive material that exhibits conductivity by itself and can form a conductive layer having a sheet resistivity of less than 10Ω/□ at 23° C. or a conductive material that can form a conductive layer having a sheet resistivity of less than 10Ω/□ at 23° C. after being sintered is preferable.

The conductive composition is not particularly limited. For example, a composition obtained by dissolving or dispersing the conductive material in a solvent or a composition including a conductive material and a binder polymer is preferable, a composition (hereinafter, also referred to as “composition C1”) obtained by dispersing the conductive material in a solvent or a composition (hereinafter, also referred to as “composition C2”) including a conductive material and a binder polymer is more preferable, and the composition (composition C1) obtained by dispersing the conductive material in a solvent is still more preferable.

As the conductive composition, for example, a well-known conductive paste, a conductive ink, or a plating-forming ink described below can also be used.

The conductive material is not particularly limited, and examples thereof will be shown below. In particular, (a) is preferable.

(a) a single metal or an alloy having a shape of particles, a cluster, crystal, a tube, a fiber, a wire, a rod, a film, or the like

(b) metal oxide particles

(c) Conductive Organic Material such as conductive polymer particles and Superconductor Particles

(d) an organometallic compound

(e) conductive materials other than (a) to (e)

(a) Single Metal or Alloy having Shape of Particles, Cluster, Crystal, Tube, Fiber, Wire, Rod, Film, or the like:

As the single metal or the alloy having a shape of particles, a cluster, crystal, a tube, a fiber, a wire, a rod, a film, or the like, from the viewpoint of further improving dispersibility, a single metal or an alloy having a shape of particles (hereinafter, also referred to as conductive particles”) is more preferable. In addition, from the viewpoint of applicability of a wiring board to precision equipment, it is preferable that the single metal or the alloy is nano-sized. As the single metal or the alloy, a single metal selected from the group consisting of gold, silver, copper, nickel, aluminum, platinum, and palladium or an alloy of two or more kinds of the above-described metals is preferable, gold, silver, copper, or an alloy thereof is more preferable from the viewpoints of a resistance value, a cost, a sintering temperature, and the like, and silver is preferable from the viewpoints of a sintering temperature and antioxidation.

As the single metal or the alloy having a shape of particles, a cluster, crystal, a tube, a fiber, a wire, a rod, a film, or the like, gold nanoparticles, silver nanoparticles, or copper nanoparticles are preferable, and silver nanoparticles are more preferable.

(b) Metal Oxide Particles:

“Metal oxide” refers to a compound that does not substantially include non-oxidized metal and specifically refers to a compound for which a peak derived from oxidized metal is detected and a peak derived from a metal is not detected in crystal analysis by X-ray diffraction. Although not particularly limited thereto, not substantially including non-oxidized metal represents that the content of non-oxidized metal is 1 mass % or less with respect to the metal oxide particles.

Examples of the metal oxide of the metal oxide particles include an oxide of copper, silver, nickel, gold, platinum, palladium, indium, tin, or the like. The metal oxides may be used alone or as a mixture of two or more kinds.

As the metal oxide, an oxide, copper, silver, nickel, or tin is preferable, an oxide of copper or silver is more preferable, and a copper oxide is still more preferable. As the copper oxide, copper (I) oxide or copper (II) oxide is preferable, and copper (II) oxide is more preferable from the viewpoint of easy availability.

The upper limit value of the average particle diameter of the metal oxide particles is preferably less than 1 μm and more preferably less than 200 nm. In addition, it is preferable that the lower limit value of the average particle diameter of the metal oxide particles is 1 nm or more. The average particle diameter of the metal oxide particles refers to the number average value of particle diameters of primary particles of freely selected 100 metal oxide particles by observation with a scanning electron microscope (SEM).

(c) Conductive Organic Material Such as Conductive Polymer and Superconductor

Examples of the conductive organic material such as a conductive polymer and the superconductor include polyaniline, polythiophene, and polyphenylene vinylene.

In addition, examples of the conductive organic material include polyethylenedioxythiophene (PEDOT) doped with polystyrene sulfonic acid (PPS) (PEDOT/PSS).

(d) Organometallic Compound

“Organometallic compound” described herein refers to a compound that is decomposed by heating such that metal precipitates.

Examples of the organometallic compound include chlorotriethylphosphinegold, chlorotrimethylphosphinegold, chlorotriphenylphosphinegold, a silver 2,4-pentanedionate complex, a silver trimethylphosphine (hexafluoroacetylacetonate) complex, and a silver hexafluoropentanedionate cyclooctanediene complex.

(e) Others

Examples of the conductive materials other than (a) to (e) include an acrylic resin as a resist material or a linear insulating material and a silane compound that forms silicon by heating. These materials may be dispersed as particles or may be dissolved in a solvent.

Examples of the silane compound that forms silicon by heating include trisilane, pentasilane, cyclotrisilane, and 1,1′-biscyclobutasilane.

In addition, from the viewpoint of further reducing the defect ratio of the formed conductive substrate, it is preferable that the conductive composition further includes a solvent and a major component of the solvent is water.

Here, “major component” refers to a component of which the mixing amount (mass ratio) in the solvent of the conductive composition is the largest.

In a case where the conductive composition includes water, the content of water is preferably more than 50 mass %, more preferably 55 mass % or more, still more preferably 60 mass % or more, still more preferably 80 mass % or more, and most preferably 90 mass % or more with respect to the total mass of the solvent including the conductive composition. The upper limit value of the content of water is, for example, 100 mass % or less with respect to the total mass of the solvent in the composition C1.

Hereinafter, the composition C1 and the composition C2 will be described.

(Composition C1) It is preferable that the composition C1 includes a conductive material, a solvent, and a dispersant. In addition, the composition C1 may further include other components such as a polymerizable compound having an ethylenically unsaturated group or a polymerization initiator.

Examples of the conductive material in the composition C1 include existing conductive materials.

The viscosity of the composition C1 is preferably 1 to 20 mPas.

It is preferable that the composition C1 is a colloidal liquid in which the conductive material is dispersed in a dispersion medium.

As the conductive material in the composition C1, conductive particles are preferable, and silver nanoparticles are more preferable.

From the viewpoints of stability and melting temperature, the average particle diameter of the conductive particles is preferably 0.1 to 50 nm and more preferably 1 to 20 nm.

The average particle diameter of the conductive particles refers to the number average value of particle diameters of primary particles of freely selected 100 conductive particles.

From the viewpoint of further improving dispersion stability and metal film forming properties in the step of sintering the conductive composition layer in the step X8 described below, the content of the conductive material in the composition C1 is preferably 10 to 95 mass % and more preferably 30 to 80 mass % with respect to the total mass of the composition.

From the viewpoints of suppressing oxidation of the formed conductive layer and reducing a volume resistance value, it is preferable that the composition C1 includes silver colloidal particles in which silver nanoparticles form a colloidal state.

The configuration of the silver colloidal particles is not particularly limited, and examples thereof include a configuration in which a dispersant is attached to surfaces of the silver nanoparticles, a configuration in which surfaces of silver nanoparticles as cores are coated with a dispersant, and a configuration in which silver particles and a dispersant are uniformly mixed with each other. In particular, the configuration in which surfaces of silver nanoparticles as cores are coated with a dispersant or and the configuration in which silver particles and a dispersant are uniformly mixed with each other is preferable. The silver colloidal particles having each of the configurations can be appropriately prepared using a well-known method.

From the viewpoint of further improving temporal stability of the dispersibility in the composition and/or the viewpoint of further reducing the resistance value of the formed conductive layer, the average particle diameter of the silver colloidal particles is preferably 1 to 400 nm and more preferably 1 to 70 nm. The average particle diameter of the silver colloidal particles can be measured using a dynamic light scattering method (Doppler scattered light analysis) as a median diameter (D50) based on a volume particle diameter.

In addition, in a case where the composition C1 includes silver nanoparticles, the composition C1 may include, in addition to the silver nanoparticles, silver submicron particles having an average particle diameter of a submicron size (for example, the average particle diameter is 1 μm or less) that is more than that of the silver nanoparticles. By using the nano-sized silver nanoparticles and the submicron-sized silver submicron particles in combination, the melting point of the silver nanoparticles decreases in the vicinity of the silver submicron particles. Therefore, an excellent conductive path is likely to be obtained.

In addition, in a case where the composition C1 includes silver nanoparticles, from the viewpoint that migration of the conductive layer can be suppressed, it is preferable that the composition C1 includes particles of a metal other than silver (hereinafter, referred to as “other metal particles”) in addition to the silver nanoparticles, and it is more preferable that the composition C1 is a mixed colloidal liquid including the silver nanoparticles and the other metal particles.

It is preferable that the metal other than silver is more noble than hydrogen in ionization series.

As the metal that is more noble than hydrogen in ionization series, gold, copper, silver, platinum, palladium, rhodium, iridium, osmium, ruthenium, or rhenium is preferable, and gold, copper, silver, platinum, or palladium is more preferable.

The metals other than silver may be used alone or in combination of two or more kinds.

In a case where the composition C1 is the mixed colloidal liquid, silver and the other metal may form alloy colloidal particles or may form colloidal particles having a structure such as a core-shell structure of a multilayer structure. The particles of the metal other than silver may be nano-sized particles or submicron-sized particles.

Examples of the solvent in the composition C1 include water and an organic solvent. Among these, water is preferable.

The organic solvent is not particularly limited, and examples thereof include: a hydrocarbon such as toluene, dodecane, tetradecane, cyclododecene, n-heptane, or n-undecane; a saturated aliphatic monohydric alcohol such as ethanol, isopropyl alcohol, or butanol; an alkanediol such as propanediol, butanediol, or pentanediol; an alkylene glycol such as ethylene glycol; a glycol monoether such as diethylene glycol monoisobutyl ether, ethylene glycol monobutyl ether, ethylene glycol monoisobutyl ether, ethylene glycol isopropyl ether, ethylene glycol monomethyl ether, or diethylene glycol monobutyl ether; and glycerin.

In addition, from the viewpoint of further reducing the defect ratio of the formed conductive substrate, it is preferable that the composition C1 further includes a solvent and a major component of the solvent is water.

Here, “major component” refers to a component of which the mixing amount (mass ratio) in the solvent of the composition C1 is the largest.

In a case where the composition C1 includes water, the content of water is preferably more than 50 mass %, more preferably 55 mass % or more, still more preferably 60 mass % or more, still more preferably 80 mass % or more, and most preferably 90 mass % or more with respect to the total mass of the solvent including the composition C1. The upper limit value of the content of water is, for example, 100 mass % or less with respect to the total mass of the solvent in the composition C1.

In addition, from the viewpoint of further improving the dispersion stability of the conductive material, the content of the solvent in the composition C1 is preferably 2 to 98 mass %, more preferably 25 to 80 mass %, still more preferably 50 to 80 mass %, and still more preferably 55 to 80 mass % with respect to the total mass of the composition.

In a case where the composition C1 includes water, it is also preferable that one or more solvents selected from the group consisting of diethylene glycol monoisobutyl ether, ethylene glycol monobutyl ether, ethylene glycol monoisobutyl ether, ethylene glycol isopropyl ether, ethylene glycol monomethyl ether, and diethylene glycol monobutyl ether are used in combination as a dispersion medium other than water. In addition, it is preferable that one or more solvents selected from the group consisting of butanol, propanediol, butanediol, pentanediol, ethylene glycol, and glycerin are further used in combination.

As described above, the composition C1 may include a dispersant.

From the viewpoint of further improving the dispersion stability of the conductive particles (in particular, silver colloidal particles) in the composition, as the dispersant, a hydroxy acid or a salt having a carboxy group or a hydroxyl group in which the number of carboxy groups in a molecule is more than or equal to the number of hydroxyl groups in a molecule is preferable.

Examples of the hydroxy acid or the salt thereof include: an organic acid such as citric acid, malic acid, tartaric acid, or glycolic acid; an ionic compound such as trisodium citrate, tripotassium citrate, trilithium citrate, monopotassium citrate, disodium hydrogen citrate, potassium dihydrogen citrate, disodium malate, disodium tartrate, potassium tartrate, potassium sodium tartrate, potassium hydrogen tartrate, sodium hydrogen tartrate, or sodium glycolate; and a hydrate thereof. In particular, trisodium citrate, tripotassium citrate, trilithium citrate, disodium malate, disodium tartrate, or a hydrate thereof is preferable.

The dispersants may be used alone or in combination of two or more kinds.

From the viewpoint of further improving the storage stability of the conductive particles and the viewpoint of further reducing the resistance value of the formed conductive layer, the content of the hydroxy acid or the salt thereof in the composition C 1 is preferably 0.5 to 30 mass %, more preferably 1 to 20 mass %, and still more preferably 1 to 10 mass % with respect to the total mass of the composition.

The composition C1 may include a polymerizable compound having an ethylenically unsaturated group (hereinafter, referred to as “ethylenically unsaturated polymerizable compound”).

As the ethylenically unsaturated polymerizable compound, from the viewpoint further improving curing properties and strength, a compound (polyfunctional ethylenically unsaturated compound) having two or more ethylenically unsaturated groups in a molecule is preferable, and a compound having three or more ethylenically unsaturated groups in a molecule is more preferable.

As the ethylenically unsaturated polymerizable compound, for example, a (meth)acrylate compound, a vinylbenzene compound, or a bismaleimide compound is preferable, and a polyvalent (meth)acrylate compound is more preferable.

Examples of the polyvalent (meth)acrylate compound include an ester compound of a polyhydric alcohol and acrylic acid or methacrylic acid. In addition, for example, an oligomer having several (meth)acryloyloxy groups in a molecule and a molecular weight of several hundreds to several thousands may also be used, the oligomer being called urethane (meth)acrylate, polyester (meth)acrylate, or epoxy (meth)acrylate.

Examples of the polyfunctional (meth)acrylate compound include a polyfunctional (meth)acrylate compound having 3 to 6 (meth)acryloyloxy groups in a molecule.

Examples of the polyfunctional (meth)acrylate compound having 3 or more (meth)acryloyloxy groups in a molecule include: a polyol poly(meth)acrylate such as trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, or dipentaerythritol hexa(meth)acrylate; and a urethane (meth)acrylate obtained by reaction of polyisocyanate and a hydroxyl group-containing (meth)acrylate such as hydroxyethyl (meth)acrylate.

The content of the ethylenically unsaturated polymerizable compound in the composition C1 is preferably 5 to 80 mass % and more preferably 10 to 50 mass % with respect to the total solid content of the composition.

The composition C1 may include a polymerization initiator.

The polymerization initiator may be any of a thermal polymerization initiator or a photopolymerization initiator.

Examples of the thermal polymerization initiator include a thermal radical generator. Specifically, for example, a peroxide initiator such as benzoyl peroxide or azobisisobutyronitrile and an azo initiator can be used.

Examples of the photopolymerization initiator include a photoradical generator. Specifically, for example, (a) an aromatic ketone, (b) an onium salt compound, (c) an organic peroxide, (d) a thio compound, (e) a hexaarylbiimidazole compound, (f) a ketoxime ester compound, (g) a borate compound, (h) an azinium compound, (i) an active ester compound, (j) a compound having carbon halogen bond, or (k) a pyridium compound can be used.

The content of the polymerization initiator in the composition C1 is preferably 0.1 to 50 mass % and more preferably 1.0 to 30.0 mass % with respect to the total solid content of the composition.

In order to suppress fluidity, the composition C1 may further include a high viscosity material.

The composition C1 may further include a reducing agent.

As the reducing agent, for example, tannic acid or hydroxy acid is preferable. Examples of the tannic acid include gallotannic acid and Chinese gallotannin.

The reducing agents may be used alone or in combination of two or more kinds.

The content of the reducing agent is preferably 0.01 to 6 g and more preferably 0.02 to 1.5 g with respect to 1 g of the conductive particles.

(Composition C2)

It is preferable that the composition C2 includes a conductive material and a binder polymer.

Examples of the conductive material in the composition C2 include existing conductive materials.

As the conductive material in the composition C2, conductive particles are preferable, and silver nanoparticles are more preferable. Examples of the above-described conductive particles and silver nanoparticles that may be included in the composition C2 are the same as the conductive particles and the silver nanoparticles that may be included in the composition C1.

The binder polymer in the composition C2 is not particularly limited, and a well-known binder polymer can be used.

Examples of the binder polymer include a thermoplastic resin such as a polyester resin, a (meth)acrylic resin, a polyethylene resin, a polystyrene resin, or a polyamide resin. In addition, the binder polymer may be a thermosetting resin such as an epoxy resin, an amino resin, a polyimide resin, or a (meth)acrylic resin.

A mixing ratio (mass ratio) between the conductive material and the binder polymer in the composition C2 is not particularly limited and is, for example, 10/90 to 90/10 and preferably 20/80 to 80/20.

In order to further adjust the viscosity, the composition C2 may include a solvent.

The solvent is not particularly limited as long as it can dissolve the components of the composition C2. From the viewpoint of further reducing the defect ratio of the formed conductive substrate, it is preferable a major component of the solvent is water.

Here, “major component” refers to a component of which the mixing amount (mass ratio) in the solvent of the composition C2 is the largest.

In a case where the composition C2 includes water, the content of water is preferably more than 50 mass %, more preferably 55 mass % or more, still more preferably 60 mass % or more, still more preferably 80 mass % or more, and most preferably 90 mass % or more with respect to the total mass of the solvent including the composition C2. The upper limit value of the content of water is, for example, 100 mass % or less with respect to the total mass of the solvent in the composition C2.

As the conductive composition, a plating-forming ink may also be used.

The plating-forming ink refers to an ink formed of a composition for forming a plated layer and a plating liquid, and refers to an ink with which a metal layer (conductive layer) can be formed by electroless plating on a plated layer formed of the composition for forming a plated layer.

In order to enable electroless plating on the plated layer formed of the composition for forming a plated layer, the composition for forming a plated layer includes an electroless plating catalyst or a precursor thereof or includes compound having a functional group (hereinafter, referred to as “interactive group”) that interacts (for example, forms an ionic bond, a coordinate bond, a hydrogen bond, or a covalent bond) with the electroless plating catalyst or the precursor thereof.

It is preferable that the composition for forming a plated layer includes a compound having an interactive group and a solvent. It is preferable that the composition for forming a plated layer further includes a polymerization initiator and a polymerizable compound.

The plating-forming ink and a usage configuration thereof can refer to the description of well-known documents such as WO2016/159136A.

<Procedure of Step X4>

A method of supplying the conductive composition to the opening portion 7 in the photosensitive resin layer 3A of the laminate 30 shown in FIG. 4 is not particularly limited, and examples thereof include spin coating using a spinner, spray coating, ink jet coating, roll coating, screen printing, offset printing, gravure printing, letterpress printing, flexographic printing, and various application methods using a blade coater, a die coater, a calendar coater, a meniscus coater, and a bar coater.

<<Step X5>>

The step X5 is a step of drying the conductive composition layer formed on the substrate 1 in the step X4 by heating.

Examples of the drying method include heating and drying using an oven, an electromagnetic wave ultraviolet lamp, an infrared heater, a halogen heater, and the like and vacuum drying.

From the viewpoint of causing drying to proceed sufficiently, the lower limit value of the drying temperature is, for example, 40° C. In addition, the upper limit value of the drying temperature is, for example, 150° C. and, from the viewpoint of further reducing the defect ratio of the formed conductive substrate, is preferably lower than 120° C. In particular, the drying temperature is preferably 50° C. or higher and lower than 120° C.

The drying time is preferably 1 minute to several hours.

From the viewpoint of further reducing the defect ratio of the formed conductive substrate, the thickness (dry thickness) of the conductive composition layer obtained through the step X5 is, for example, 5.0 μm or less, preferably 3.0 μm or less, and more preferably 2.5 μm or less. The lower limit value is, for example, 0.1 μm or more and preferably 0.2 μm or more.

<<Step X6>>

The step X6 is a step of exposing the photosensitive resin layer 3A (the photosensitive resin layer obtained through the step X5) in which the conductive composition is supplied to the opening portion 7. As shown in FIG. 7, in the step X6, the photosensitive resin layer 3A is exposed (preferably entire surface exposure) from a surface (back surface of the substrate 1) of the substrate 1 opposite to the photosensitive resin layer 3A. By performing the step X6, the acid-decomposable group in the acid-decomposable resin of the exposed photosensitive resin layer 3A is deprotected by action of an acid such that the solubility in an alkali stripper increases. That is, the polarity of the photosensitive resin layer 3A changes. By performing the step X6, the exposed photosensitive resin layer 3A is easily stripped in the stripping step of the following step X7.

As the light source used for the exposure, any light source can be appropriately selected and used as long as it can emit light in a wavelength range (for example, 365 nm or 405 nm) with which the photosensitive resin layer 3A can be exposed. Specific examples of the light source include an ultrahigh pressure mercury lamp, a high-pressure mercury lamp, a metal halide lamp, and a light emitting diode (LED). In particular, from the viewpoint of the spectral sensitivity of the photosensitive resin layer, it is preferable to emit light having a wavelength of 365 nm.

The exposure amount is preferably 5 to 1000 mJ/cm², more preferably 100 to 1000 mJ/cm², and still more preferably 300 to 800 mJ/cm².

In the exposure treatment, the exposure may be performed through the substrate 1 from the surface (back surface of the substrate 1) of the substrate 1 opposite to the photosensitive resin layer 3A, or may be performed from a surface (front surface of the substrate 1) of the substrate 1 on the photosensitive resin layer 3A side. From the viewpoint of further reducing the defect ratio of the formed conductive substrate, it is preferable that the exposure is performed through the substrate 1 from the surface (back surface of the substrate 1) of the substrate 1 opposite to the photosensitive resin layer 3A.

<<Step X7>>

Step X7: a step of removing the photosensitive resin layer that is exposed by performing the step X6 using a stripper including water as a major component.

FIG. 8 shows a laminate 50 obtained through the step X7. The laminate 50 includes: the substrate 1; and the patterned conductive composition layer 8A on the substrate 1.

<Stripper>

The stripper includes water as a major component.

Here, “major component” refers to a component of which the mixing amount (mass ratio) in the stripper is the largest.

The content of water in the stripper is preferably more than 50 mass %, more preferably 55 mass % or more, still more preferably 60 mass % or more, still more preferably 80 mass % or more, and most preferably 90 mass % or more with respect to the total mass of the stripper. The upper limit value of the content of water is, for example, 100 mass % or less and preferably 95 mass % or less with respect to the total mass of the solvent including the stripper.

In order to promote stripping, it is preferable that the stripper further includes an organic amine.

The organic amine is not particularly limited. For example, a primary to tertiary alkylamine or alkanolamine is preferable, and examples thereof include diethylamine (boiling point: 55.5° C.), triethylamine (boiling point: 89° C.), monoethanolamine (boiling point: 170° C.), diethanolamine (boiling point: 280° C.), and N-methyl-ethanolamine (boiling point: 155° C.).

The boiling point of the organic amine is, for example, 300° C. or lower and, in order to easily sinter the conductive composition layer in the step X8 without interrupting the sintering of the conductive material, is preferably 250° C. or lower, more preferably 180° C. or lower, and still more preferably 100° C. or lower. The lower limit value of the boiling point of the organic amine is not particularly limited and is, for example, 30° C.

As the organic amine, in particular, a primary to tertiary alkylamine or alkanolamine having a boiling point of 180° C. or lower is preferable, diethylamine (boiling point: 55.5° C.), triethylamine (boiling point: 89° C.), or monoethanolamine (boiling point: 170° C.) is more preferable, and diethylamine (boiling point: 55.5° C.) or triethylamine (boiling point: 89° C.) is still more preferable.

The upper limit value of the content of the organic amine in the stripper is preferably less than 50 mass %, more preferably 40 mass % or less, and still more preferably 30 mass % or less with respect to the total mass of the stripper.

The lower limit value of the content of the organic amine in the stripper is preferably 1 mass % or more, more preferably 3 mass % or more, and still more preferably 5 mass % or more with respect to the total mass of the stripper.

The stripper may further include a water-soluble organic solvent and a surfactant.

<Stripping Treatment>

A stripping method is not particularly limited and may be any of puddle stripping, shower stripping, spin stripping, dip stripping, or the like.

Here, shower stripping will be described. The exposed portion can be removed by blowing the stripper to the exposed photosensitive resin layer by showering. In addition, it is preferable to remove a residue by blowing a cleaning agent by showering after the stripping while rubbing the exposed portion with a brush or the like.

The liquid temperature of the stripper is, for example, 20° C. to 60° C. In addition, from the viewpoint of further reducing the defect ratio of the formed conductive substrate, the upper limit value of the liquid temperature of the stripper is preferably lower than 50° C. The lower limit value is preferably 5° C. or higher.

<<Step X8>>

The step X8 is a step of sintering the patterned conductive composition layer 8A obtained through the step X7.

From the viewpoint of further reducing the resistance value of the conductive layer and the viewpoint of further improving the manufacturing efficiency, as a method of sintering the patterned conductive composition layer 8A in the step X8, thermal sintering or photosintering is preferable.

In a case where the patterned conductive composition layer 8A is thermally sintered, from the viewpoint of further improving substrate heat resistance and the viewpoint of further reducing the resistance value of the conductive layer in the formed conductive substrate, the heating temperature is, for example, 90° C. or higher, preferably 100° C. or higher, more preferably 120° C. or higher, and still more preferably 130° C. or higher. In addition, the upper limit value is, for example, 200° C. or lower, preferably 180° C. or lower, and more preferably 160° C. or lower.

A heating method is not particularly limited, and examples thereof include a method of using a well-known gear oven in the related art.

In addition, from the viewpoint of further improving the manufacturing efficiency and the viewpoint of further reducing the resistance value of the conductive layer in the formed conductive substrate, the heating time is preferably 0.5 to 120 minutes, more preferably 1 to 80 minutes, still more preferably 1 to 60 minutes, and still more preferably 10 to 60 minutes. In a case where the patterned conductive composition layer 8A is photosintered, the kind of a ray to be irradiated is not particularly limited as long as the conductive composition layer can be sintered, and light including ultraviolet light is preferable. The irradiation energy is preferably 10 to 10000 mJ/cm², more preferably 20 to 6000 mJ/cm², and still more preferably 30 to 5000 mJ/cm². In addition, although depending on the irradiation energy, the irradiation time is not particularly limited and may be determined depending on whether or not typical exposure or flash exposure is performed. In a case where the flash exposure is performed, the irradiation time is preferably 0.1 to 10 ms (milliseconds), more preferably 0.2 to 5 ms, and still more preferably 0.5 to 4 ms.

From the viewpoint of further reducing the resistance value of the conductive layer, it is preferable that the sintering treatment of the patterned conductive composition layer 8A is performed at a higher temperature than the boiling point of the organic amine in the stripper.

By performing the step X8, the conductive composition layer 8A is sintered to obtain the conductive substrate 10 shown in FIG. 1.

The thickness of the patterned conductive layer 2 obtained through the step X8 is as described above.

The sheet resistance value at 23° C. of the patterned conductive layer 2 obtained through the step X8 is preferably lower than 10Ω/□, more preferably lower than 5Ω/□, and still more preferably lower than 2Ω/□. The lower limit value is not particularly limited and is, for example, 10⁻²Ω/□ or higher.

### Second Embodiment

A second embodiment of the method of manufacturing the conductive substrate includes a step X1B described below, the step X2, the step X3, the step X4, the step X5, the step X6, the step X7, and the step X8 in this order.

Step X1B: a step of applying a positive tone photosensitive resin composition to a substrate to form a photosensitive resin layer.

The second embodiment of the method of manufacturing the conductive substrate is the same as the first embodiment of the method of manufacturing the conductive substrate, except that the step X1B is performed instead of the step X1A.

The substrate and the positive tone photosensitive resin composition used in the step X1B are the same as the substrate and the positive tone photosensitive resin composition used in the step X1A.

The conductive substrate 10 shown in FIG. 1 is formed with the second embodiment of the method of manufacturing the conductive substrate.

It is preferable that the step X1B is a step of applying the positive tone photosensitive resin composition to the substrate to form a coating film and drying the obtained coating film to form a photosensitive resin layer.

From the viewpoint of transfer properties and resolution ability, the lower limit value of the thickness of the photosensitive resin layer is preferably 1.0 μm or more. The upper limit value is, for example, 30.0 μm or less, preferably 15.0 μm or less, more preferably 10.0 μm or less, and still more preferably 5.0 μm or less.

Examples of an application method include a well-known method such as slit coating, spin coating, curtain coating, or ink jet coating.

The drying temperature is not particularly limited and is, for example, 80° C. to 150° C. In addition, the drying time is not particularly limited and is, for example, 1 to 60 minutes.

As the first embodiment and the second embodiment, the method of manufacturing the conductive substrate including the step X5 is described. However, the step X5 is an optional step and does not need to be included in the method of manufacturing the conductive substrate.

[Use]

The conductive substrate obtained using the method of manufacturing the conductive substrate can be used for various uses. Examples of the uses of the conductive substrate include a touch panel (touch sensor), an antenna, an electromagnetic wave shielding material, a semiconductor chip, various electrical wiring boards, flexible printed circuits (FPC), chip on film (COF), tape automated bonding (TAB), a multilayer interconnection board, and a motherboard. It is preferable that the conductive substrate is used for a touch sensor, an antenna, or an electromagnetic wave shielding material.

In a case where the conductive substrate is applied to a touch sensor, the patterned conductive layer in the conductive substrate functions as a detection electrode or a lead-out wiring in the touch sensor.

The touch panel is not particularly limited as long as it includes the touch sensor, and examples thereof include a device in which the above-described touch sensor and various display devices (for example, a liquid crystal display device or an organic electro-luminescence (EL) display device) are used in combination.

Examples of a detection method in the touch sensor and the touch panel include a well-known type such as a resistive membrane type, a capacitive type, an ultrasonic wave type, an electromagnetic induction type, or an optical type. In particular, a capacitive type touch sensor or touch panel is preferable.

Examples of the touch panel include a so-called in-cell type (for example, that shown in FIGS. 5, 6, 7, and 8 of JP2012-517051A), a so-called on-cell type (for example, that shown in FIG. 19 of JP2013-168125A or that shown in FIGS. 1 and 5 of JP2012-089102A), an one glass solution (OGS) type, a touch-on-lens (TOL) type (for example, that shown in FIG. 2 of JP2013-054727A), various out-cell types (for example, so-called GG, G1, G2, GFF, GF2, GF1, or G1F), and other configurations (for example, that shown in FIG. 6 of JP2013-164871A).

Examples of the touch panel include that shown in paragraph “0229” of JP2017-120345A.

In addition, a method of manufacturing a touch panel is not particularly limited and can refer to a well-known method of manufacturing a touch panel except that a touch sensor including the above-described conductive substrate is used.

### EXAMPLES

Hereinafter, the present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

Unless specified otherwise, “part(s)” and “%” represent “part(s) by mass” and “mass %”.

In addition, the following abbreviations represent the following compounds, respectively.

“AA”: acrylic acid (manufactured by Tokyo Chemical Industry Co., Ltd.)

“ATHF”: 2-tetrahydrofuranyl acrylate (synthetic product)

“CHA”: cyclohexyl acrylate (manufactured by Tokyo Chemical Industry Co., Ltd.)

“EA”: ethyl acrylate (manufactured by Tokyo Chemical Industry Co., Ltd.)

“MAA”: methacrylic acid (manufactured by Tokyo Chemical Industry Co., Ltd.)

“PGMEA”: propylene glycol monomethyl ether acetate (manufactured by Showa Denko K.K.)

“TBA”: tert-butyl acrylate (manufactured by Fujifilm Wako Pure Chemical Corporation)

“BMA”: benzyl methacrylate (manufactured by Fujifilm Wako Pure Chemical Corporation)

“PMPMA”: 1,2,2,6,6-pentamethyl-4-piperidyl methacrylate (manufactured by Fujifilm Wako Pure Chemical Corporation)

“MMA”: methyl methacrylate (manufactured by Tokyo Chemical Industry Co., Ltd.)

“V-601”: dimethyl 2,2′-azobis(2-methylpropionate) (manufactured by Fujifilm Wako Pure Chemical Corporation.)

[Preparation of Photosensitive Transfer Members 1 to 5]

[Preparation of Photosensitive Transfer Member 1]

<Preparation of Positive Tone Photosensitive Resin Composition 1>

The following components were mixed with each other to obtain a mixed solution. Next, the mixture was filtered through a polytetrafluoroethylene filter having a pore diameter of 0.2 μm to obtain a positive tone photosensitive resin composition 1.
Acid-decomposable resin (the following polymer 1): 9.64 parts
Photoacid generator (the following compound A-1): 0.25 parts
Surfactant (the following surfactant C): 0.01 parts
Additive (the following compound D (basic compound)): 0.1 parts
PGMEA: 90.00 parts

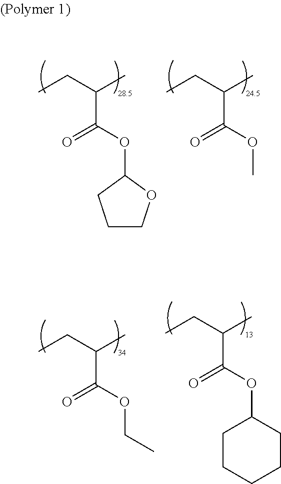

In the polymer 1, a numerical value shown in each of constitutional units is represented by mass %.

The weight-average molecular weight of the polymer 1 is 25,000. The glass transition temperature of the polymer 1 is 25° C.

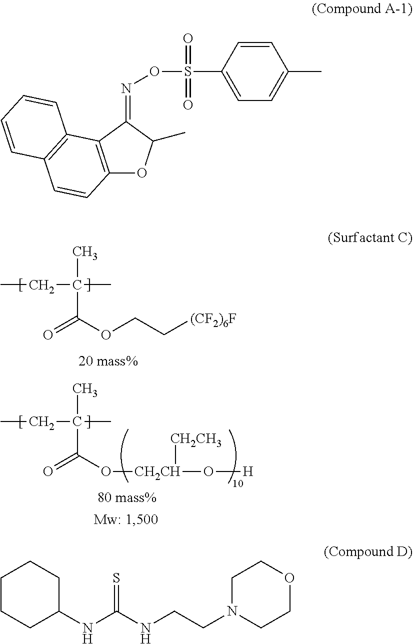

<Preparation of Composition 1 for forming Interlayer>

According to the following formula, a composition 1 for forming an interlayer was prepared.
Cellulose resin (METOLOSE (registered trade name) 60SH-03, manufactured by Shin-Etsu Chemical Co., Ltd.): 3.5 parts
Surfactant (MEGAFACE (registered trade name) F444, manufactured by DIC Corporation): 0.1 parts
Pure water: 33.7 parts
Methanol: 62.7 parts

<Preparation of Photosensitive Transfer Member 1>

The composition 1 for forming an interlayer was applied to a temporary support 1 (a polyethylene terephthalate film having a thickness of 12 μm, LUMIRROR 12QS62, manufactured by Toray industries Inc., haze value: 0.43%) using a slit nozzle such that the dry film thickness thereof was 2.0 μm, and was dried to form an interlayer. The above-described positive tone photosensitive resin composition 1 was applied to the interlayer such that the dry thickness (refer to “Dry Thickness (μm) of Photosensitive Resin Layer) in Table 1) was as shown in Table 1. As a result, a coating film was formed. Next, the coating film was dried by hot air at 90° C. to form a photosensitive resin layer 1. Finally, a polyethylene film (manufactured by Tredegar Corporation, OSM-N) as a protective film was pressure-bonded to the obtained photosensitive resin layer 1. As a result, a photosensitive transfer member 1 was prepared.

[Preparation of Photosensitive Transfer Member 2]

A photosensitive transfer member 2 was prepared using the same production method as that of the photosensitive transfer member 1, except that the following temporary support 2 was used instead of the temporary support 1.

<Manufacturing of Temporary Support 2>

Using the following method, a temporary support 2 in which a coating layer was formed on a single surface of a polyethylene terephthalate film was manufactured.

(Extrusion Molding)

A pellet of polyethylene terephthalate obtained by using a titanium compound described in JP5575671B as a polymerization catalyst was dried such that the moisture content was 50 ppm or less, was put into a hopper of a single-screw kneading extruder having a diameter of 30 mm, and was melt-extruded at 280° C. The melt was caused to pass through a filter (pore diameter: 3 μm) and was extruded through a cooling roll at 25° C. from a die. As a result, a non-stretched film was obtained. The extruded melt was attached to the cooling roll using a static electricity application method.

(Stretching and Application)

By performing application of a coating liquid for a coating layer and sequential biaxial stretching on the obtained non-stretched film, the temporary support 2 including the substrate having a thickness of 10 μm (polyethylene terephthalate film) and the coating layer having a thickness of 50 nm was obtained. The application of the coating liquid for a coating layer was performed in the process of sequential biaxial stretching of the non-stretched film after the uniaxial stretching of the non-stretched film. The haze value of the temporary support 2 was 0.31%. The coating liquid for a coating layer was prepared according to the following formula.

<<Coating Liquid for Coating Layer>>
Acrylic polymer (AS-563A, manufactured by Daicel FineChem Ltd., solid content: 27.5 mass %): 167 parts
Nonionic surfactant (NAROACTY (registered trade name) CL 95, manufactured by Sanyo Chemical Industries Ltd., solid content: 100 mass %): 0.7 parts
Anionic surfactant (RAPISOL (registered trade name) A-90, manufactured by NOF Corporation, a water diluent having a solid content of 1 mass %): 55.7 parts
Carnauba wax dispersion (CELLOSOL (registered trade name) 524, manufactured by Chukyo Yushi Co., Ltd., solid content: 30 mass %): 7 parts
Carbodiimide compound (CARBODILITE (registered trade name) V-02-L2, manufactured by Nisshinbo Chemical Inc., a water diluent having a solid content of 10 mass %): 20.9 parts
Matting agent (SNOWTEX (registered trade name) XL, manufactured by Nissan Chemical Industries Ltd., solid content: 40 mass %): 2.8 parts
Water: 743 parts

[Preparation of Photosensitive Transfer Member 3]

A photosensitive transfer member 3 was prepared using the same production method as that of the photosensitive transfer member 1, except that the thickness of the interlayer was adjusted to 5.0 μm.

[Preparation of Photosensitive Transfer Member 4]

A photosensitive transfer member 4 was prepared using the same preparation method as that of the photosensitive transfer member 1, except that the positive tone photosensitive resin composition 1 was directly applied to the temporary support 1 without providing the interlayer.

[Preparation of Photosensitive Transfer Member 5]

A photosensitive transfer member 5 was prepared using the same production method as that of the photosensitive transfer member 1, except that the following positive tone photosensitive resin composition 2 was used instead of the positive tone photosensitive resin composition 1.

<Preparation of Positive Tone Photosensitive Resin Composition 2>

The following components were mixed with each other to obtain a mixed solution. Next, the mixture was filtered through a polytetrafluoroethylene filter having a pore diameter of 0.2 μm to obtain a positive tone photosensitive resin composition 2.
Acid-decomposable resin (the following polymer 2): 9.64 parts
Photoacid generator (the following compound A-2): 0.25 parts
Surfactant (the surfactant C): 0.01 parts
Additive (the compound D): 0.1 parts
PGMEA: 90.00 parts

Polymer 2: a compound having the following structure (glass transition temperature: 90° C.; weight-average molecular weight: 20,000; a numerical value described in each of the following constitutional units is represented by mass %)

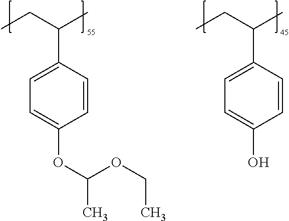

Compound A-2: A Compound Having the Following Structure

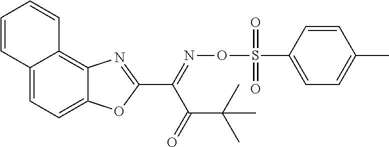 [SMILES: Cc1ccc(S(=O)(=O)O/N=C(\C(=O)C(C)(C)C)c2nc3c(ccc4ccccc43)o2)cc1]

[Manufacturing of Conductive Substrates According to Examples 1 to 6]

Using the obtained photosensitive transfer members 1 to 6, conductive substrates were manufactured as follows.

[Step X1A: Step of Forming Photosensitive Resin Layer on Substrate]

The above-described photosensitive transfer member was bonded (transfer step) while stripping a protective film from a PET film (manufactured by Toyobo Co., Ltd., COSMOSHINE A 4300 (polyethylene terephthalate film, thickness: 38 μm)) as a substrate. As a result, a laminate was formed.

The above-described transfer step was performed using a vacuum laminator (manufactured by MCK Co., Ltd.) under conditions of substrate temperature: 60° C., roller temperature: 120° C., linear pressure: 0.8 MPa, and linear velocity: 1.0 m/min.

In the above-described transfer step, the surface of the photosensitive resin layer that was exposed by stripping the protective film from the photosensitive transfer member was brought into contact with the surface of the PET film as the substrate.

The transmittance of the PET film with respect to light in a visible range of 400 to 700 nm was 92.3%.

[Step X2: Step of Exposing Photosensitive Resin Layer in Patterned Manner]

Using the obtained laminate, the step X2 was performed in the following procedure. An exposure mask having a predetermined mask pattern (drawing region: 3 cm□, line-and-space (L/S): 10 μm/10 μm) and the temporary support were closely attached to each other. Next, using an ultrahigh pressure mercury lamp (wavelength: 365 nm), the photosensitive resin layer was exposed in a patterned manner through the exposure mask and the temporary support (exposure step). Table 1 shows the exposure amount (mJ/cm²).

[Step X3: Step of Developing Exposed Photosensitive Resin Layer with Alkali Developer to Form Opening Portion that Penetrates Photosensitive Resin Layer]

Next, after stripping the temporary support, shower development was performed for 30 seconds using a 1.0 mass % sodium carbonate aqueous solution (corresponding to the alkali aqueous solution developer) at 25° C.

Through the steps X1A, X2, and X3, the photosensitive resin layer including the opening portion penetrating the photosensitive resin layer was formed on the substrate. In a step X4 described below, a conductive ink was supplied to the opening portion to form a conductive composition layer.

[Steps X4 to X8: Manufacturing of Conductive Substrate]

<Steps X4 and X5: Step of Supplying Conductive Composition and Step of Drying Conductive Composition Layer>

Next, the conductive composition shown in Table 1 (refer to “Kind of Conductive Composition” in Table 1) was applied using a bar coater to the substrate including the photosensitive resin layer having the opening portion penetrating the photosensitive resin layer such that the dry thickness was as shown in Table 1 (refer to “Dry Thickness (μm) of Conductive Composition Layer” in Table 1. As a result, a coating film (conductive composition layer) was formed. Next, the above-described coating film (conductive composition) was dried for 10 minutes in an oven controlled to a temperature shown in Table 1 (refer to “Drying Temperature (° C.) of Conductive Composition Layer” in Table 1).

(Conductive Composition)

Conductive compositions A to D shown in Table 1 are as follows.

Both of the conductive compositions A and D include a solvent, and a major component of the solvent is water.

A: aqueous silver nano ink manufactured by DOWA Electronics Materials Co., Ltd.

B: a photosintering nanoink CJ-0104, manufactured by Ishihara Chemical Co., Ltd.)

C: DOTITE XA-3609 (corresponding to a silver paste) manufactured by Fujikura Kasei Co., Ltd.

D: aqueous nano ink SW-1020 manufactured by Bando Chemical Industries Co., Ltd.

Next, whether or not the conductive composition is a composition in which the photosensitive resin layer is substantially insoluble was determined using the following method.

(Preparation of Test Substrate and Measurement of Thickness)

The positive tone photosensitive resin composition used in the step X1 was applied to the surface of the polyethylene terephthalate film to form a coating film such that the dry thickness was 3 μm. Next, by drying the coating film by hot air at 90° C. for 0.5 hours, a test substrate in which the photosensitive resin layer was formed on the polyethylene terephthalate film was prepared.

Next, the thickness of the photosensitive resin layer in the test substrate was measured. Specifically, using scanning electron microscopy (SEM), a cross section including a direction perpendicular to a main surface of the layer was observed, the thickness of the layer was measured at 10 or more points based on the obtained observation image, and an average value T1 (μm) was calculated.

(Dipping Treatment)

The above-described test substrate was dipped in the conductive composition (temperature: 30° C.) used in the step X4 for 5 minutes. After being dipped for a predetermined time, the test substrate was extracted from the conductive composition and was dried at 90° C.

(Measurement of Thickness of Test Substrate after Dipping Treatment)

Next, the thickness of the photosensitive resin layer in the test substrate after the dipping treatment was measured. Specifically, a cross section including a direction Perpendicular to a main surface of the layer was observed using a SEM, the thickness of the layer was measured at 10 or more points based on the obtained observation image, and an average value T2 (μm) was calculated.

(Determination)

In a case where a value (F) calculated from Expression (1) is 95% or more, it was determined that the conductive composition was a composition in which the photosensitive resin layer was substantially insoluble (that is, in a case where a change in the thickness of the photosensitive resin layer after the dipping treatment was 5% or less, it was determined that the conductive composition was a composition in which the photosensitive resin layer was substantially insoluble).

F=(T2/T1)×100 Expression (1):

The results are shown in Table 1.

<Step X6: Exposure Step>

The entire surface of the laminate formed through the step X5 was exposed using an exposure method shown in Table 1 (refer to “Exposure Method” in Table 1).

(Exposure Method)

Exposure methods A to C shown in Table 1 are as follows.

A: using a ultrahigh pressure mercury lamp (including a wavelength of 365 nm), the entire surface of the substrate was irradiated with an energy of 500 mJ/cm² from a back surface of the substrate (that is, a surface of the substrate opposite to a surface where the photosensitive resin layer was provided)

B: using a ultrahigh pressure mercury lamp (including a wavelength of 365 nm), the entire surface of the substrate was irradiated With an energy of 500 mJ/cm² from a front surface of the substrate (that is, the surface of the substrate where the photosensitive resin layer was provided)

C: the substrate was not exposed

<Step X7: Stripping Step>

Next, the exposed laminate was developed with a stripper adjusted to a temperature shown in Table 1 (refer to “Temperature of Stripper” and “Kind of Stripper” in Table 1), and the exposed photosensitive resin layer was stripped to form a patterned conductive composition layer on the substrate.

(Stripper)

Strippers A to C shown in Table 1 are as follows.

A: 5 mass % triethylamine aqueous solution (boiling point: 89° C.)

B: 5 mass % monoethanolamine aqueous solution (boiling point: 170° C.)

C: 5 mass % diethanolamine aqueous solution (boiling point: 280° C.)

<Step X8: Sintering Step>

A sintering step was performed on the laminate obtained through the step X7 using a sintering method shown in Table 1 (refer to “Sintering Method” in Table 1) to obtain a conductive substrate.

(Sintering Method)

Sintering methods A and B shown in Table 1 are as follows.

A: the laminate was heated using a drying oven at a sintering temperature shown in Table 1 for 60 minutes

B: the laminate was heated using ab oven at a temperature shown in Table for 60 minutes after irradiated with light for 2 milliseconds at an energy of 4000 mJ/cm² using a flash irradiation device equipped with a xenon lamp (UX-A3091EM, manufactured by Sugawara Laboratories Inc.)

[Manufacturing of Conductive Substrate According to Example 7]

[Preparation of Positive Tone Photosensitive Resin Composition 3]

<Synthesis of Acid-Decomposable Resin (Polymer 3)>

(Synthesis of ATHF)

Acrylic acid (72.1 g, 1.0 mol) and hexane (72.1 g) were added to a three-neck flask and cooled to 20° C. After adding camphorsulfonic acid (7.0 mg, 0.03 mmol) and 2-dihydrofuran (77.9 g, 1.0 mol) dropwise, the solution was stirred at 20° C.±2° C. for 1.5 hours, was heated to 35° C., and was subsequently stirred for 2 hours. KYOWAAD 200 (filter medium, aluminum hydroxide powder, manufactured by Kyowa chemical Industry Co., Ltd.) and KYOWAAD 1000 (filter medium, hydrotalcite powder, manufactured by Kyowa chemical Industry Co., Ltd.) were put into a Nutsche filter in this order. Next, the reaction solution was filtered to obtain a filtrate. By adding hydroquinone monomethyl ether (MEHQ, 1.2 mg) to the obtained filtrate and concentrating the solution under reduced pressure at 40° C., 140.8 g of acrylic acid tetrahydrofuran-2-yl ester (ATHF) was obtained as a colorless oily matter (yield: 99.0%).

(Synthesis of Acid-Decomposable Resin (Polymer 3))

PGMEA (75.0 g) was put into a three-neck flask and was heated to 90° C. in a nitrogen atmosphere. A solution including ATHF (40.0 g), AA (2.0 g), EA (20.0 g), MMA (22.0 g), CHA (16.0 g), V-601 (4.0 g), and PGMEA (75.0 g) was added dropwise to the three-neck flask solution maintained at 90° C.±2° C. for 2 hours. By stirring the solution at 90° C.±2° C. for 2 hours after the dropwise addition, a polymer 3 (concentration of solid contents: 40.0 mass %) was obtained.

The contents (mass %: ATHF/AA/EA/MMA/CHA) of the constitutional units in the polymer 3 are 40/2/20/22/16. ATHF corresponds to the constitutional unit having an acid-decomposable group, and AA corresponds to the constitutional unit having an acid group.

The weight-average molecular weight of the polymer 3 is 25,000.

The glass transition temperature (Tg) of the polymer 3 is 34° C., and the acid value thereof is 15.6 mgKOH/g.

<Preparation of Positive Tone Photosensitive Resin Composition 3>

Components shown below were mixed with each other to obtain a mixture having a concentration of solid contents of 10 mass %. Next, the mixture was filtered through a polytetrafluoroethylene filter having a pore diameter of 0.2 μm to obtain a positive tone photosensitive resin composition 3.
Acid-decomposable resin (the polymer 3): 100 parts
Photoacid generator (the compound A-1): 3 parts
Additive (the compound D (basic compound)): 1.6 parts
Surfactant (the surfactant C): 0.1 parts
Additive (the following compound E): 4.5 parts
PGMEA: an amount (parts) adjusted such that the concentration of solid contents was 10 mass %

Compound E: 9,10-Dibutoxyanthracene

[Manufacturing of Conductive Substrate]

The steps X2 to X8 were performed using the same method as described above in a procedure shown in Table 1, except that a step X1B was performed using the positive tone photosensitive resin composition 3 in the following procedure.

<Step X1B: Step of Forming Photosensitive Resin Layer on Substrate>

The positive tone photosensitive resin composition 3 was applied to a PET film as a substrate (manufactured by Toyobo Co., Ltd., COSMOSHINE A4300 (polyethylene terephthalate film, thickness: 38 μm)) such that the dry thickness was as shown in Table 1 (refer to “Dry thickness (μm) of Photosensitive Resin Layer” in Table 1). As a result, a coating film was formed. Next, by drying the coating film was dried by hot air at 90° C., a laminate including the photosensitive resin layer on the substrate was formed.

The transmittance of the PET film with respect to light in a visible range of 400 to 700 nm was 92.3%.

[Manufacturing of Conductive Substrate According to Example 8]

[Preparation of Photosensitive Transfer Member 6]

A photosensitive transfer member 6 was prepared using the same production method as that of the photosensitive transfer member 1, except that the following positive tone photosensitive resin composition 4 was used instead of the positive tone photosensitive resin composition 1.

<Preparation of Positive Tone Photosensitive Resin Composition 4>

The following components were mixed with each other to obtain a mixed solution. Next, the mixture was filtered through a polytetrafluoroethylene filter having a pore diameter of 0.2 μm to obtain a positive tone photosensitive resin composition 2.
Acid-decomposable resin (the polymer 1): 9.64 parts
Photoacid generator (the compound A-1): 0.25 parts
Surfactant (the surfactant C): 0.01 parts
Additive (the compound D): 0.09 parts
Additive (the following compound F): 0.01 parts
PGMEA: 90.00 parts

Compound F: 1,2,3-benzotriazole (Manufactured by Tokyo Chemical Industry Co., Ltd.)

[Manufacturing of Conductive Substrate]

Using the obtained photosensitive transfer member 6, a conductive substrate was manufactured with the method described above in “[Manufacturing of Conductive Substrates according to Examples 1 to 6]”.

[Manufacturing of Conductive Substrate According to Example 9]

A conductive substrate was manufactured using the same method as the method of manufacturing the conductive substrate according to Example 7, except that conditions were changed as shown in Table 1.

[Manufacturing of Conductive Substrate According to Example 10]

[Preparation of Positive Tone Photosensitive Resin Composition 5]

<Synthesis of Acid-Decomposable Resin (Polymer 4)>

PGMEA (75.0 g) was put into a three-neck flask and was heated to 90° C. in a nitrogen atmosphere. A solution including TBA (30.0 g), PMPMA (1.0 g), AA (3.0 g), MMA (26.0 g), MBA (5.0 g), EA (25.0 g), CHA (10.0 g), V-601 (4.0 g), and PGMEA (75.0 g) was added dropwise to the three-neck flask solution maintained at 90° C. 2° C. for 2 hours. By stirring the solution at 90° C.±2° C. for 2 hours after the dropwise addition, a polymer 4 (concentration of solid contents: 40.0 mass %) was obtained.

The contents (mass %: TBA/PMPMA/AA/MMA/BMA/EA/CHA) of the constitutional units in the polymer 4 are 30/1/3/26/5/25/10. TBA corresponds to the constitutional unit having an acid-decomposable group, and AA corresponds to the constitutional unit having an acid group.

The weight-average molecular weight of the polymer 4 is 25,000.

The glass transition temperature (Tg) of the polymer 4 is 28° C.

<Preparation of Positive Tone Photosensitive Resin Composition 5>

Components shown below were mixed with each other to obtain a mixture having a concentration of solid contents of 10 mass %. Next, the mixture was filtered through a polytetrafluoroethylene filter having a pore diameter of 0.2 μm to obtain a positive tone photosensitive resin composition 5.
Acid-decomposable resin (the polymer 4): 100 parts
Photoacid generator (the compound A-1): 3 parts
Additive (the compound D (basic compound)): 1.6 parts
Surfactant (the following surfactant W-2): 0.1 parts
PGMEA: an amount (parts) adjusted such that the concentration of solid contents was 10 mass %

W-2: MEGAFACE R08 (Manufactured by DIC Corporation; Fluorine and Silicon-Based)

[Manufacturing of Conductive Substrate]

The steps X2 to X8 were performed using the same method as described above in a procedure shown in Table 1, except that a step X1B was performed using the positive tone photosensitive resin composition 5 in the following procedure.

<Step X1B: Step of Forming Photosensitive Resin Layer on Substrate>

The positive tone photosensitive resin composition 6 was applied to a PET film as a substrate (manufactured by Toyobo Co., Ltd., COSMOSHINE A4300 (polyethylene terephthalate film, thickness: 38 μm)) such that the dry thickness was as shown in Table 1 (refer to “Dry thickness (μm) of Photosensitive Resin Layer” in Table 1). As a result, a coating film was formed. Next, by drying the coating film was dried by hot air at 90° C., a laminate including the photosensitive resin layer on the substrate was formed.

The transmittance of the PET film with respect to light in a visible range of 400 to 700 nm was 92.3%.

[Manufacturing of Conductive Substrate According to Example 11]

A conductive substrate was manufactured using the same method as the method of manufacturing the conductive substrate according to Example 2, except that conditions were changed as shown in Table 1.

[Manufacturing of Conductive Substrate According to Example 12]

A conductive substrate was manufactured using the same method as the method of manufacturing the conductive substrate according to Example 2, except that conditions were changed as shown in Table 1.

[Manufacturing of Conductive Substrate According to Comparative Example 1]

Using the obtained photosensitive transfer member 5, a conductive substrate was manufactured with the method described above in “[Manufacturing of Conductive Substrates according to Examples 1 to 6]”.

[Manufacturing of Conductive Substrate according to Comparative Example 2]

A conductive substrate was manufactured using the same method as the method of manufacturing the conductive substrate according to Example 7, except that conditions were changed as shown in Table 1.

[Manufacturing of Conductive Substrate according to Comparative Example 3]

A conductive substrate was manufactured using the same method as the method of manufacturing the conductive substrate according to Comparative Example 1, except that conditions were changed as shown in Table 1.

[Evaluation]

Using the conductive substrate obtained using the method of manufacturing the conductive substrate according to each of Examples and Comparative Examples, the following evaluation was performed.

<Pattern Defect Ratio>

By observing the substrate in which 10 patterns with L/S=10/10 (μm) were continuously formed with an optical microscope, a pattern defect ratio was obtained. Specifically, a 200 μm×200 μm region corresponding 100 visual fields was extracted from a range of 30 mm in a longitudinal direction, and the pattern was observed. The frequency at which any defect of disconnection, stripping of the conductive layer from the substrate, short-circuit in the opening portion (in other words, short-circuit between line portions), or adhesion of a stripped material was observed in the conductive pattern was measured, and was evaluated based on the following evaluation standards.

“A”: the pattern defect ratio was less than 20 visual fields

“B”: the pattern defect ratio was 20 visual fields or more and less than 40 visual fields

“C”: the pattern defect ratio was 40 visual fields or more and less than 60 visual fields

“D”: the pattern defect ratio was 60 visual fields or more and less than 80 visual fields

“E”: the pattern defect ratio was 80 visual fields or more

The results are shown in Table 1.

<Evaluation of Conductivity>

The conductivity was evaluated based on the sheet resistance value. The sheet resistance value (temperature: 23° C.) was measured with a four-probe method using a resistivity meter (manufactured by Mitsubishi Chemical Corporation, LORESTA GX MCP-T700) by bringing four probes into contact with a conductive film, and was evaluated based on the following evaluation standards.

“A”: the sheet resistance value is lower than 2 [Ω/□]

“B”: the sheet resistance value is 2 [Ω/□] or higher and lower than 5 [Ω/□]

“C”: the sheet resistance value is 5 [Ω/□] or higher and lower than 10 [Ω/□]

“D”: the sheet resistance value is 10 [Ω/□] or higher

The results are shown in Table 1.

Hereinafter, Table 1 will be shown.

In the field “Properties of Conductive Composition” of Table 1, a case where the conductive composition was a composition in which the photosensitive resin layer was insoluble is represented by “A”, and a case where the conductive composition was a composition in which the photosensitive resin layer was soluble is represented by “B”. Whether or not the conductive composition was a composition a composition in which the photosensitive resin layer was insoluble was determined using the above-described method.

In addition, RT in the field “Temperature [° C.] of Stripper] of Table 1 represents room temperature.

In addition, in the field “Sintering Temperature and Temperature of Organic Amine” of Table 1, a case where the temperature of the organic amine in the stripper was lower than the sintering temperature” is represented by “A”, and a case where the temperature of the organic amine in the stripper was higher than the sintering temperature” is represented by “B”.

TABLE 1

| | Each of Steps X1 to X3 | | | | | | | | |
|---|---|---|---|---|---|---|---|---|---|
| | | | | Dry | | Each of Steps X4 to X8 | | | |
| | | | | Thickness | | | | Dry | Drying |
| | | | | of Photo- | | | | Thickness of | Temperature of |
| | Photosensitive | | | sensitive | | | | Conductive | Conductive |
| | Resin | Film Forming | | Resin | Exposure | Kind of | Properties | Composition | Composition |
| | Composition | Method | | Layer | Amount | Conductive | of Conductive | Layer | Layer |
| | Kind | Method | Note | [μm] | [mJ/cm²] | Composition | Composition | [μm] | [° C.] |
| Example 1 | Positive Tone | Transfer | Photosensitive | 3.0 | 100 | A | A | 1.0 | 90 |
| | Photosensitive | | Transfer | | | | | | |
| | Resin | | Member 1 | | | | | | |
| | Composition 1 | | | | | | | | |
| Example 2 | Positive Tone | Transfer | Photosensitive | 3.0 | 90 | A | A | 0.2 | 80 |
| | Photosensitive | | Transfer | | | | | | |
| | Resin | | Member 2 | | | | | | |
| | Composition I | | | | | | | | |
| Example 3 | Positive Tone | Transfer | Photosensitive | 3.0 | 80 | A | A | 0.2 | 80 |
| | Photosensitive | | Transfer | | | | | | |
| | Resin | | Member 2 | | | | | | |
| | Composition 1 | | | | | | | | |
| Example 4 | Positive Tone | Transfer | Photosensitive | 3.0 | 100 | D | A | 0.5 | 120 |
| | Photosensitive | | Transfer | | | | | | |
| | Resin | | Member 3 | | | | | | |
| | Composition 1 | | | | | | | | |
| Example 5 | Positive Tone | Transfer | Photosensitive | 3.0 | 100 | D | A | 0.9 | 45 |
| | Photosensitive | | Transfer | | | | | | |
| | Resin | | Member 4 | | | | | | |
| | Composition 1 | | | | | | | | |
| Example 6 | Positive Tone | Transfer | Photosensitive | 3.0 | 75 | D | A | 0.6 | 130 |
| | Photosensitive | | Transfer | | | | | | |
| | Resin | | Member 5 | | | | | | |
| | Composition 2 | | | | | | | | |
| Example 7 | Positive Tone | Application | — | 10.0 | 150 | A | A | 1.0 | 50 |
| | Photosensitive | | | | | | | | |
| | Resin | | | | | | | | |
| | Composition 3 | | | | | | | | |
| Example 8 | Positive Tone | Transfer | Photosensitive | 3.0 | 100 | A | A | 0.2 | 80 |
| | Photosensitive | | Transfer | | | | | | |
| | Resin | | Member 6 | | | | | | |
| | Composition 4 | | | | | | | | |
| Example 9 | Positive Tone | Application | — | 10.0 | 140 | A | A | 1.0 | 50 |
| | Photosensitive | | | | | | | | |
| | Resin | | | | | | | | |
| | Composition 3 | | | | | | | | |
| Example 10 | Positive Tone | Application | — | 3.0 | 100 | D | A | 1.0 | 80 |
| | Photosensitive | | | | | | | | |
| | Resin | | | | | | | | |
| | Composition 5 | | | | | | | | |
| Example 11 | Positive Tone | Transfer | Photosensitive | 3.0 | 100 | A | A | 0.2 | 80 |
| | Photosensitive | | Transfer | | | | | | |
| | Resin | | Member 2 | | | | | | |
| | Composition 1 | | | | | | | | |
| Example 12 | Positive Tone | Transfer | Photosensitive | 3.0 | 100 | A | A | 0.2 | 80 |
| | Photosensitive | | Transfer | | | | | | |
| | Resin | | Member 2 | | | | | | |
| | Composition 1 | | | | | | | | |
| Comparative | Positive Tone | Transfer | Photosensitive | 3.0 | 100 | B | B | 0.6 | 130 |
| Example 1 | Photosensitive | | Transfer | | | | | | |
| | Resin | | Member 5 | | | | | | |
| | Composition 2 | | | | | | | | |
| Comparative | Positive Tone | Application | — | 25.0 | 150 | C | B | 3.0 | 60 |
| Example 2 | Photosensitive | | | | | | | | |
| | Resin | | | | | | | | |
| | Composition 3 | | | | | | | | |
| Comparative | Positive Tone | Transfer | Photosensitive | 3.0 | 100 | A | A | 0.6 | 130 |
| Example 3 | Photosensitive | | Transfer | | | | | | |
| | Resin | | Member 5 | | | | | | |
| | Composition 2 | | | | | | | | |

| | Each of Steps X4 to X8 | | | | | | | |
|---|---|---|---|---|---|---|---|---|
| | | | | | | Temperature | Evaluation | |
| | | | Temper- | | | of Sintering | Result | |
| | | Kind | ature of | | Sintering | Temperature and | Pattern | |
| | Exposure | of | Stripper | Sintering | Temperature | Temperature of | Defect | Conduc- |
| | Method | Stripper | [° C.] | Method | [° C.] | Organic Amine | Ratio | tivity |
| Example 1 | A | A | 50 | A | 150 | A | B | A |
| Example 2 | A | A | RT | A | 120 | A | A | B |
| Example 3 | A | A | RT | A | 150 | A | A | A |
| Example 4 | A | B | RT | A | 100 | B | C | B |
| Example 5 | A | A | RT | A | 150 | A | D | A |
| Example 6 | A | A | RT | A | 130 | A | D | A |
| Example 7 | B | A | 40 | A | 150 | A | C | A |
| Example 8 | A | B | RT | A | 150 | B | A | B |
| Example 9 | A | C | 40 | A | 180 | B | B | B |
| Example 10 | A | A | 30 | A | 150 | A | D | A |
| Example 11 | A | A | RT | A | 90 | A | A | D |
| Example 12 | A | A | RT | A | 110 | A | A | C |
| Comparative | A | A | RT | A | 130 | A | E | A |
| Example 1 | | | | | | | | |
| Comparative | A | A | 50 | B | 150 | A | E | A |
| Example 2 | | | | | | | | |
| Comparative | C | A | RT | A | 130 | A | E | A |
| Example 3 | | | | | | | | |

It is obvious from the results shown in Table 1 that the defect ratio of the conductive layer in the conductive substrate can be reduced with the method of manufacturing the conductive substrate according to Examples (refer to “Pattern Defect Ratio” in the table).

In addition, it can be verified from a comparison between Examples 3 and 1 that, in a case where the temperature of the stripper in the step X7 is lower than 50° C., the defect ratio of the conductive layer is further reduced.

In addition, it can be verified from a comparison between Example 3 and Examples 2, 4, 11, and 12 that, in a case where the sintering temperature in the step X8 is 100° C. or higher (preferably 120° C. or higher and more preferably 130° C. or higher), the resistance value of the conductive layer is further reduced.

In addition, it can be verified from a comparison between Example 3 and Examples 4 to 6 that, in a case where the drying temperature of the conductive composition layer in the step X5 is 50° C. or higher and lower than 120° C., the defect ratio of the conductive layer is further reduced.

In addition, it was verified from a comparison between Examples 3 and 7 that, in a case where the exposure treatment in the step X6 is a step of exposing the photosensitive resin layer from the substrate back surface through the substrate, the defect ratio of the conductive layer is further reduced.

In addition, it can be verified from a comparison between Example 3 and Examples 8 and 9 that, in a case where the boiling point of the organic amine in the stripper is 180° C. or lower, the defect ratio of the conductive layer tends to be further reduced.

In addition, it can be verified from a comparison between Example 3 and Examples 8 and 9 that, in a case where the sintering treatment in the step X8 is performed at a temperature higher than the boiling point of the organic amine in the stripper, the resistance value of the conductive layer is further reduced.

It can be verified from a comparison between Examples 3 and 10 that, in a case where the acid-decomposable group in the acid-decomposable resin of the photosensitive resin layer is an acetal group, the defect ratio of the conductive layer is further reduced.

It is obvious from the results shown in Table 1 that the defect ratio of the conductive layer is high with the method of manufacturing the conductive substrate according to Comparative Examples.

### EXPLANATION OF REFERENCES

1: substrate
2: patterned conductive layer
3, 3A: photosensitive resin layer
5: temporary support
6: mask
6a: opening portion of mask
7: opening portion
8A, 8B: conductive composition layer
10: conductive substrate
20, 30, 40, 40′, 50: laminate

What is claimed is:

1. A method of manufacturing a conductive substrate including a substrate and a patterned conductive layer that is disposed on the substrate, the method comprising:
the following step X1, the following step X2, the following step X3, the following step X4, the following step X6, the following step X7, and the following step X8 in this order,
wherein in the step X4, a photosensitive resin layer is substantially insoluble in a conductive composition,
Step X1: a step of forming a photosensitive resin layer formed of a positive tone photosensitive resin composition on a substrate;
Step X2: a step of exposing the photosensitive resin layer in a patterned manner;
Step X3: a step of developing the exposed photosensitive resin layer with an alkali developer to form an opening portion that penetrates the photosensitive resin layer;
Step X4: a step of supplying a conductive composition to the opening portion in the photosensitive resin layer to form a conductive composition layer;
Step X6: a step of exposing the photosensitive resin layer in which the conductive composition layer is formed in the opening portion;
Step X7: a step of removing the exposed photosensitive resin layer using a stripper including water as a major component; and
Step X8: a step of sintering the conductive composition layer on the substrate by heating.

2. The method of manufacturing a conductive substrate according to claim 1,
wherein the conductive composition includes a solvent, and
a major component of the solvent is water.

3. The method of manufacturing a conductive substrate according to claim 1, further comprising:
the following step X5 that is provided between the step X4 and the step X6, wherein a heating temperature in the step X5 is 50° C. or higher and lower than 120° C., Step X5: a step of drying the conductive composition layer by heating.

4. The method of manufacturing a conductive substrate according to claim 1,
wherein the substrate is transparent, and
in the step X6, the photosensitive resin layer is exposed through the substrate from a surface of the substrate opposite to a side where the photosensitive resin layer is provided.

5. The method of manufacturing a conductive substrate according to claim 1,
wherein the stripper further includes an organic amine.

6. The method of manufacturing a conductive substrate according to claim 5,
wherein a boiling point of the organic amine is 180° C. or lower.

7. The method of manufacturing a conductive substrate according to claim 5,
wherein in the step X8, the conductive composition layer is sintered at a temperature higher than a boiling point of the organic amine.

8. The method of manufacturing a conductive substrate according to claim 1,
wherein a temperature of the stripper in the step X7 is lower than 50° C.

9. The method of manufacturing a conductive substrate according to claim 1,
wherein the positive tone photosensitive resin composition includes a photoacid generator and a polymer having a polar group protected by a protective group that is deprotected by action of an acid.

10. The method of manufacturing a conductive substrate according to claim 9,
wherein the polar group protected by the protective group that is deprotected by action of the acid is an acetal group.

11. The method of manufacturing a conductive substrate according to claim 9,
wherein the polymer having the polar group protected by the protective group that is deprotected by action of the acid includes a constitutional unit represented by any one of Formulae A1 to A3, 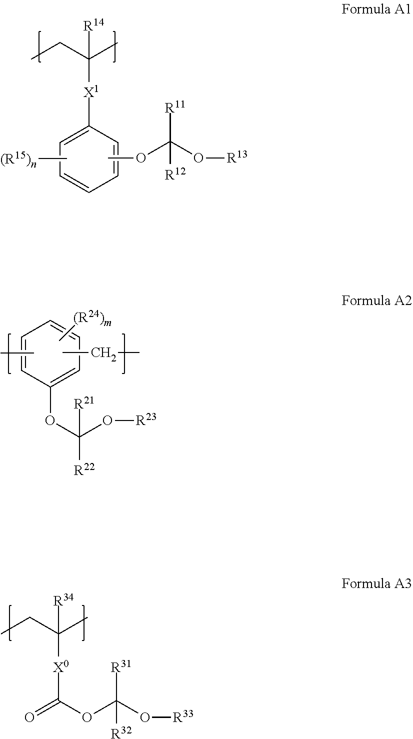
in Formula A1, R¹¹ and R¹² each independently represent a hydrogen atom, an alkyl group, or an aryl group,
at least one of R¹¹ or R¹² represents an alkyl group or an aryl group,
R¹³ represents an alkyl group or an aryl group,
R¹⁴ represents a hydrogen atom or a methyl group,
X¹ represents a single bond or a divalent linking group,
R¹⁵ represents a substituent,
n represents an integer of 0 to 4, and
R¹¹ or R¹² and R¹³ may be linked to each other to form a cyclic ether,
in Formula A2, R²¹ and R²² each independently represent a hydrogen atom, an alkyl group, or an aryl group,
at least one of R²¹ or R²² represents an alkyl group or an aryl group,
R²³ represents an alkyl group or an aryl group,
R²⁴'s each independently represent a hydroxy group, a halogen atom, an alkyl group, an alkoxy group, an alkenyl group, an aryl group, an aralkyl group, an alkoxycarbonyl group, a hydroxyalkyl group, an arylcarbonyl group, an aryloxycarbonyl group, or a cycloalkyl group,
m represents an integer of 0 to 3, and
R²¹ or R²² and R²³ may be linked to each other to form a cyclic ether, and
in Formula A3, R³¹ and R³² each independently represent a hydrogen atom, an alkyl group, or an aryl group,
at least one of R³¹ or R³² represents an alkyl group or an aryl group,
R³³ represents an alkyl group or an aryl group,
R³⁴ represents a hydrogen atom or a methyl group,
X⁰ represents a single bond or a divalent linking group, and
R³¹ or R³² and R³³ may be linked to each other to form a cyclic ether.

12. The method of manufacturing a conductive substrate according to claim 1,
wherein the step X1 is a step of forming the photosensitive resin layer on the substrate using a photosensitive transfer member including a temporary support and the photosensitive resin layer disposed on the temporary support, and
the step X1 being a step of bonding the photosensitive transfer member and the substrate to each other by bringing a surface of the photosensitive resin layer opposite to the temporary support side into contact with the substrate.

13. The method of manufacturing a conductive substrate according to claim 1,
wherein the conductive composition includes any of gold nanoparticles, silver nanoparticles, or copper nanoparticles.

14. A conductive substrate that is formed using the method of manufacturing a conductive substrate according to claim 1.

15. A touch sensor comprising:
the conductive substrate according to claim 14.

16. An antenna comprising:
the conductive substrate according to claim 14.

17. An electromagnetic wave shielding material comprising:
the conductive substrate according to claim 14.

18. The method of manufacturing a conductive substrate according to claim 2, further comprising:
the following step X5 that is provided between the step X4 and the step X6, wherein a heating temperature in the step X5 is 50° C. or higher and lower than 120° C., Step X5: a step of drying the conductive composition layer by heating.

19. The method of manufacturing a conductive substrate according to claim 2,
wherein the substrate is transparent, and
in the step X6, the photosensitive resin layer is exposed through the substrate from a surface of the substrate opposite to a side where the photosensitive resin layer is provided.

20. The method of manufacturing a conductive substrate according to claim 2,
wherein the stripper further includes an organic amine.
